(19) United States
(12) Patent Application Publication
(10) Pub. No.: US 2026/0040519 A1
(43) Pub. Date: Feb. 5, 2026

(54) SEMICONDUCTOR DEVICES

(71) Applicant: Samsung Electronics Co., Ltd., Suwon-si (KR)

(72) Inventors: JEON IL LEE, Suwon-si (KR); DAIHONG HUH, Suwon-si (KR)

(21) Appl. No.: 19/020,405

(22) Filed: Jan. 14, 2025

(30) Foreign Application Priority Data
Aug. 1, 2024 (KR) 10-2024-0102238

(51) Int. Cl. H10B 10/00; H10D 30/00; H10D 62/10; H10D 64/23; H10D 64/27

(52) U.S. Cl. CPC H10B 10/12; H10D 30/501; H10D 62/121; H10D 64/254; H10D 64/256; H10D 64/512

(57) ABSTRACT

A semiconductor device may include, a substrate; a first lower sheet pattern on the substrate; a second lower sheet pattern on the substrate; a first lower gate electrode that extends around the first lower sheet pattern; a second lower gate electrode that extends around the second lower sheet pattern; a middle sheet pattern on the first lower sheet pattern; an upper sheet pattern on the middle sheet pattern; first and second lower source/drain patterns on opposite sides of the first lower sheet pattern; first and second middle source/drain patterns on opposite sides of the middle sheet pattern; first and second upper source/drain patterns on opposite sides of the upper sheet pattern; a merged through contact that extends in the second lower source/drain pattern, the second middle source/drain pattern, and the second upper source/drain pattern; and a lower gate contact electrically connected to the second lower gate electrode.

### CROSS-REFERENCE TO RELATED APPLICATIONS

This application claims priority to Korean Patent Application No. 10-2024-0102238, filed in the Korean Intellectual Property Office on Aug. 1, 2024, the entire contents of which are hereby incorporated by reference.

### BACKGROUND OF THE INVENTION

The present disclosure relates to electronic devices, such as semiconductor devices.

A semiconductor device may be a component used to control or amplify an electrical signal in an electronic device, and various types of semiconductor devices may be manufactured. For example, a memory device may be used to store and retrieve data, while a non-memory device may be used to control or amplify an electrical signal. The semiconductor device may be a component of an electronic device and may play an important role in various fields including computers, communication equipment, consumer electronics, etc.

Among the semiconductor devices, static random access memory (SRAM) may provide high operating speed with low operating power because it may not require data refresh. An SRAM cell may include two pass transistors and two inverters forming a flip-flop circuit.

When configuring the SRAM cell, six transistors may be arranged in a single SRAM cell, and this may be a challenge for one who tries to improve the integration density of the SRAM cell. Accordingly, there is a need for research on SRAM cells to improve integration density and reliability.

### SUMMARY OF THE INVENTION

The present disclosure may provide semiconductor devices with improved integration density.

According to some embodiments of the present disclosure, the merged through contact may be disposed to be electrically connected to the lower source/drain pattern, the middle source/drain pattern, and the upper source/drain pattern, thereby improving the integration density of the semiconductor device.

According to some embodiments, the middle source/drain contact and the lower source/drain contact may be aligned in one direction, thereby improving the integration density of the semiconductor device.

According to some embodiments of the present disclosure, a semiconductor device may include, a substrate; a first lower sheet pattern on the substrate; a second lower sheet pattern on the substrate, wherein the second lower sheet pattern is spaced apart from the first lower sheet pattern in a first direction that is parallel with an upper surface of the substrate; a first lower gate electrode that extends around the first lower sheet pattern and extends in a second direction that is parallel with the upper surface of the substrate and intersects the first direction; a second lower gate electrode that extends around the second lower sheet pattern and extends in the second direction; a middle sheet pattern on the first lower sheet pattern, wherein the middle sheet pattern is spaced apart from the first lower sheet pattern in a third direction that is perpendicular to the upper surface of the substrate; an upper sheet pattern on the middle sheet pattern, wherein the upper sheet pattern is spaced apart from the middle sheet pattern in the third direction; a first lower source/drain pattern and a second lower source/drain pattern on opposite sides of the first lower sheet pattern in the first direction; a first middle source/drain pattern and a second middle source/drain pattern on opposite sides of the middle sheet pattern in the first direction; a first upper source/drain pattern and a second upper source/drain pattern on opposite sides of the upper sheet pattern in the first direction; a merged through contact that extends in the second lower source/drain pattern, the second middle source/drain pattern, and the second upper source/drain pattern; and a lower gate contact that extends in the substrate and is electrically connected to the second lower gate electrode, wherein the merged through contact is spaced apart from the lower gate contact in the first direction.

According to some embodiments of the present disclosure, a semiconductor device may include, a substrate; a first lower sheet pattern on the substrate; a second lower sheet pattern on the substrate, wherein the second lower sheet pattern is spaced apart from the first lower sheet pattern in a first direction that is parallel with an upper surface of the substrate; a first lower gate electrode that extends around the first lower sheet pattern and extends in a second direction that is parallel with the upper surface of the substrate and intersects the first direction; a second lower gate electrode that extends around the second lower sheet pattern and extends in the second direction; a first middle sheet pattern on the first lower sheet pattern, wherein the first middle sheet pattern is spaced apart from the first lower sheet pattern in a third direction that is perpendicular to the upper surface of the substrate; a second middle sheet pattern on the second lower sheet pattern, wherein the second middle sheet pattern is spaced apart from the second lower sheet pattern in the third direction; a first upper sheet pattern on the first middle sheet pattern, wherein the first upper sheet pattern is spaced apart from the first middle sheet pattern in the third direction; a second upper sheet pattern on the second middle sheet pattern, wherein the second upper sheet pattern is spaced apart from the second middle sheet pattern in the third direction; a first lower source/drain pattern and a second lower source/drain pattern on opposite sides of the first lower sheet pattern in the first direction; a first middle source/drain pattern and a second middle source/drain pattern on opposite sides of the first middle sheet pattern in the first direction; a middle source/drain contact that extends in the substrate and the first lower source/drain pattern and is electrically connected to the first middle source/drain pattern; and a lower source/drain contact that is spaced apart from the middle source/drain contact in the second direction and is electrically connected to the first lower source/drain pattern, wherein the middle source/drain contact overlaps the lower source/drain contact in the second direction.

According to some embodiments of the present disclosure, a semiconductor device may include, a substrate; a first lower sheet pattern on the substrate; a second lower sheet pattern on the substrate, wherein the second lower sheet pattern is spaced apart from the first lower sheet pattern in a first direction that is parallel with an upper surface of the substrate; a first lower gate electrode that extends around the first lower sheet pattern and extends in a second direction that is parallel with the upper surface of the substrate and intersects the first direction; a second lower gate electrode that extends around the second lower sheet pattern and extends in the second direction; a first middle sheet pattern on the first lower sheet pattern, wherein the first middle sheet pattern is spaced apart from the first lower sheet pattern in a third direction that is perpendicular to the upper surface of the substrate; a second middle sheet pattern on the second lower sheet pattern, wherein the second middle sheet pattern is spaced apart from the second lower sheet pattern in the third direction; a first upper sheet pattern on the first middle sheet pattern, wherein the first upper sheet pattern is spaced apart from the first middle sheet pattern in the third direction; a second upper sheet pattern on the second middle sheet pattern, wherein the second upper sheet pattern is spaced apart from the second middle sheet pattern in the third direction; a first lower source/drain pattern and a second lower source/drain pattern on opposite sides of the first lower sheet pattern in the first direction; a first middle source/drain pattern and a second middle source/drain pattern on opposite sides of the first middle sheet pattern in the first direction; a first upper source/drain pattern and a second upper source/drain pattern on opposite sides of the first upper sheet pattern in the first direction; a middle source/drain contact that extends in the substrate and the first lower source/drain pattern and is electrically connected to the first middle source/drain pattern; a lower source/drain contact that extends in the substrate and is electrically connected to the first lower source/drain pattern, wherein the lower source/drain contact is spaced apart from the middle source/drain contact in the second direction; a merged through contact that extends in the second lower source/drain pattern, the second middle source/drain pattern, and the second upper source/drain pattern in the third direction; a lower gate contact that extends in the substrate and is electrically connected to the second lower gate electrode; and a lower wiring on a lower surface of the substrate, wherein the lower wiring electrically connects the lower gate contact and the merged through contact, wherein the middle source/drain contact overlaps the lower source/drain contact in the second direction.

### BRIEF DESCRIPTION OF THE DRAWINGS

The above and other embodiments and features of the present disclosure will become more apparent by describing in detail example embodiments thereof with reference to the attached drawings, in which:

FIG. 1 is a circuit diagram provided to explain a semiconductor device according to some embodiments;

FIG. 2 is an example layout diagram provided to explain a semiconductor device according to some embodiments;

FIG. 3 is a cross-sectional view taken along line A-A′ of FIG. 2;

FIG. 4 is a cross-sectional view taken along line B-B′ of FIG. 2.

FIG. 5 is a cross-sectional view taken along line C-C′ of FIG. 2;

FIG. 6 is a diagram provided to explain a semiconductor device according to some embodiments;

FIG. 7 is a diagram provided to explain a semiconductor device according to some embodiments;

FIG. 8 is a diagram provided to explain a semiconductor device according to some embodiments;

FIGS. 9 and 10 are diagrams provided to explain a semiconductor device according to some embodiments;

FIGS. 11 and 12 are diagrams provided to explain a semiconductor device according to some embodiments;

FIGS. 13 and 14 are diagrams provided to explain a semiconductor device according to some embodiments;

FIG. 15 is a flowchart provided to explain a method for manufacturing a semiconductor device according to some embodiments.

### DETAILED DESCRIPTION

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure. As used herein, the term “and/or” includes any and all combinations of one or more of the associated listed items.

A semiconductor device according to some embodiments may include a metal-oxide-semiconductor field effect transistor (MOSFET), and more specifically, may include a gate-all-round (GAA) transistor and a three-dimensional multi-stack semiconductor device referred to as a multi-bridge channel FET (MBCFET).

Hereinafter, a semiconductor device and a method for manufacturing the same according to some embodiments of the present disclosure will be described in detail with reference to drawings.

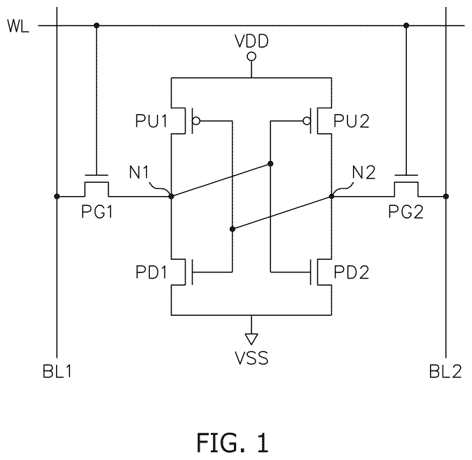

FIG. 1 is a circuit diagram provided to explain a semiconductor device according to some embodiments.

Referring to FIG. 1, the semiconductor device according to some embodiments may include at least one cell. For example, the cell may be a static random access memory (SRAM) cell. The cell may include a word line WL, a first bit line BL1, a second bit line BL2, and a plurality of transistors. FIG. 1 may be an example circuit diagram illustrating a cell of a semiconductor device.

The semiconductor device according to some embodiments may include a first pass transistor PG1, a second pass transistor PG2, a first pull-up transistor PU1, a second pull-up transistor PU2, a first pull-down transistor PD1, and a second pull-down transistor PD2.

The first pull-up transistor PU1 and the second pull-up transistor PU2 may be P-type metal-oxide-semiconductor field effect transistors (MOSFETs). The first pass transistor PG1, the second pass transistor PG2, the first pull-down transistor PD1, and the second pull-down transistor PD2 may be N-type MOSFETs. The semiconductor device may include six transistors including four NMOS transistors and two PMOS transistors. However, embodiments are not limited thereto.

Switching electrodes (e.g., gate electrodes) of the first and second pass transistors PG1 and PG2 may be (electrically) connected to the word line WL. A source pattern of the first pass transistor PG1 may be (electrically) connected to the first bit line BL1. A source pattern of the second pass transistor PG2 may be (electrically) connected to the second bit line BL2. A positive voltage (e.g., a VDD voltage) may be applied to a source pattern of the first pull-up transistor PU1. A positive voltage (e.g., a VDD voltage) may be applied to a source pattern of the second pull-up transistor PU2. A negative voltage (e.g., a VSS voltage) may be applied to the source pattern of the first pull-down transistor PD1. A negative voltage (e.g., a VSS voltage) may be applied to the source pattern of the second pull-down transistor PD2.

A drain pattern of the first pass transistor PG1, a drain pattern of the first pull-up transistor PU1, and a drain pattern of the first pull-down transistor PD1 may be (electrically) connected to a first node N1.

A drain pattern of the second pass transistor PG2, a drain pattern of the second pull-up transistor PU2, and a drain pattern of the second pull-down transistor PD2 may be (electrically) connected to a second node N2.

A switching electrode (e.g., a gate electrode) of the first pull-up transistor PU1 and a switching electrode (e.g., a gate electrode) of the first pull-down transistor PD1 may be (electrically) connected to the second node N2. A switching electrode (e.g., a gate electrode) of the second pull-up transistor PU2 and a switching electrode (e.g., a gate electrode) of the second pull-down transistor PD2 may be (electrically) connected to the first node N1. Accordingly, the first and second pull-up transistors PU1 and PU2 and the first and second pull-down transistors PD1 and PD2 may construct a latch circuit including a pair of CMOS inverters.

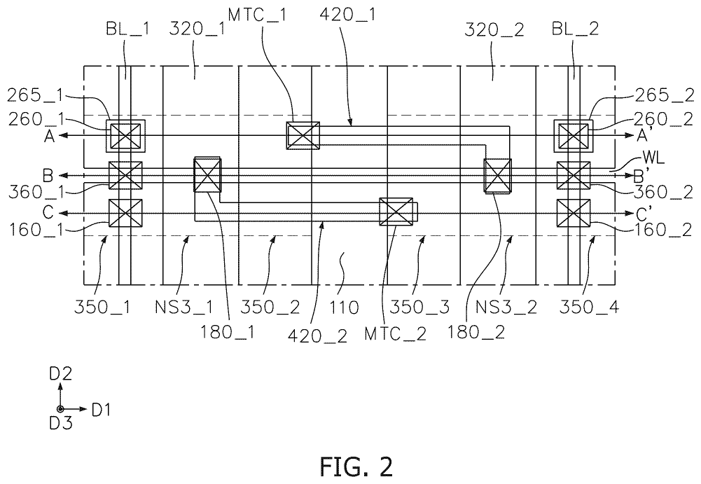

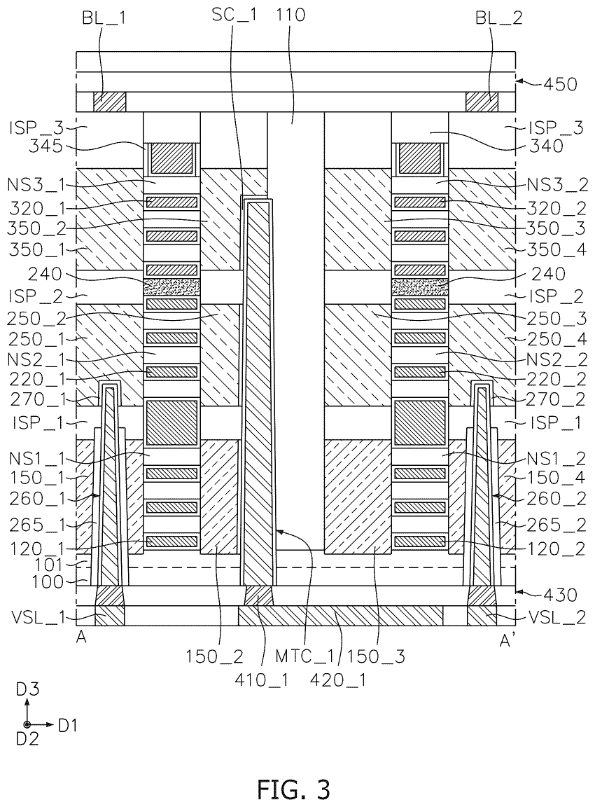

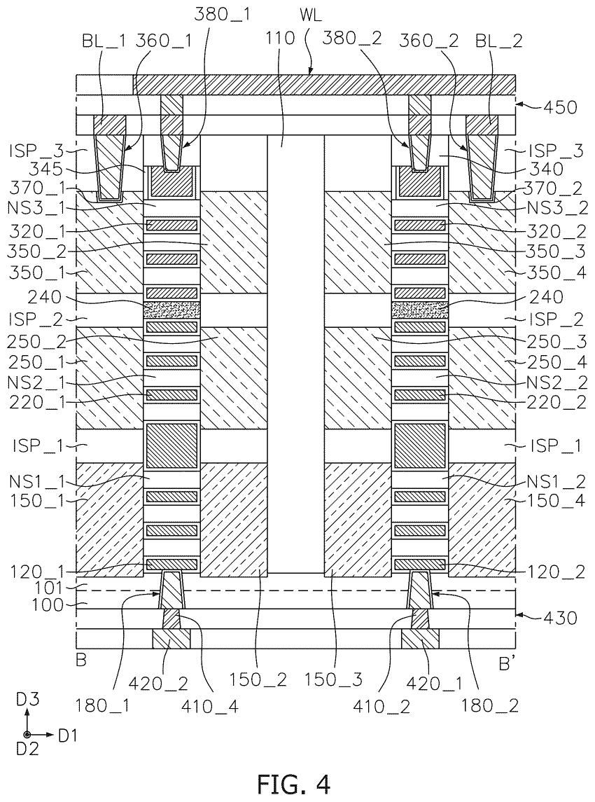

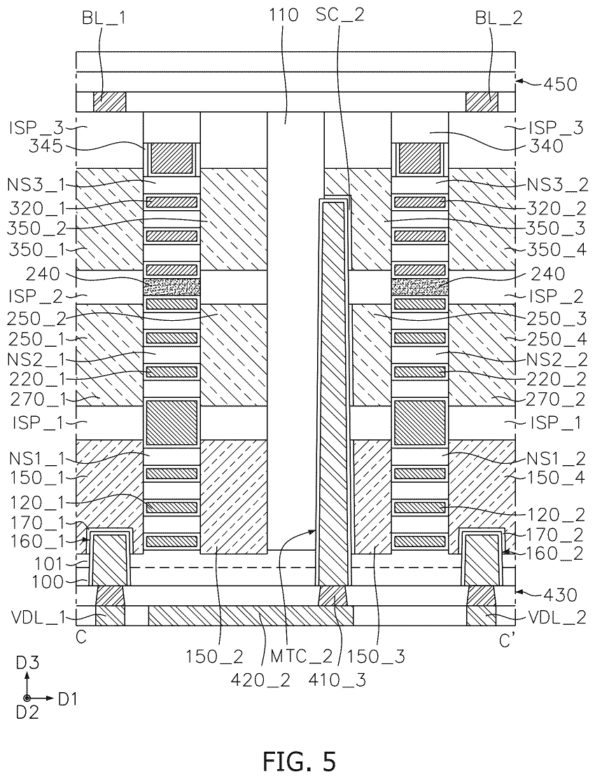

FIG. 2 is an example layout diagram provided to explain a semiconductor device according to some embodiments. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2.

Referring to FIGS. 2 to 5, the semiconductor device according to some embodiments may include a substrate 100, first and second lower sheet patterns NS1_1 and NS1_2, first and second middle sheet patterns NS2_1 and NS2_2, first and second upper sheet patterns NS3_1 and NS3_2, first and second lower gate electrodes 120_1 and 120_2, first and second middle gate electrodes 220_1 and 220_2, first and second upper gate electrodes 320_1 and 320_2, first, second, third, and fourth lower source/drain patterns 150_1, 150_2, 150_3, and 150_4, first, second, third, and fourth middle source/drain patterns 250_1, 250_2, 250_3, and 250_4, first, second, third, and fourth upper source/drain patterns 350_1, 350_2, 350_3, and 350_4, first and second lower source/drain contacts 160_1 and 160_2, first and second lower silicide films 170_1 and 170_2, first and second middle source/drain contacts 260_1 and 260_2, first and second middle silicide films 270_1 and 270_2, first and second contact insulating films 265_1 and 265_2, first and second merged through contacts MTC_1 and MTC_2, first and second through contact silicide films SC_1 and SC_2, first and second lower gate contacts 180_1 and 180_2, first and second upper gate contacts 380_1 and 380_2, etc.

The substrate 100 may include an insulating material. For example, the substrate 100 may include silicon oxide, silicon nitride, silicon oxynitride, and/or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or a combination thereof. However, embodiments are not limited thereto.

An insulating pattern 101 may be disposed on an upper surface of the substrate 100. The insulating pattern 101 may be formed (may extend) in a first direction D1. The insulating pattern 101 may protrude from the upper surface of the substrate 100 in a third direction D3. The first and second directions D1 and D2 may be parallel to the upper surface of the substrate 100. The first direction D1 may be a direction intersecting the second direction D2. The third direction D3 may be a direction perpendicular to the upper surface of the substrate 100. The third direction D3 may be a direction intersecting each of the first and second directions D1 and D2. The insulating pattern 101 may include the same material as the substrate 100.

The first lower sheet pattern NS1_1 may be disposed on the insulating pattern 101. The second lower sheet pattern NS1_2 may be disposed on the insulating pattern 101. The second lower sheet pattern NS1_2 may be disposed to be spaced apart from the first lower sheet pattern NS1_1 in the first direction D1. The second lower sheet pattern NS1_2 may be disposed at the same vertical level as the first lower sheet pattern NS1_1. For example, the second lower sheet pattern NS1_2 may overlap the first lower sheet pattern NS1_1 in the first direction D1. Herein, the term “level”, “vertical level”, “height”, or the like may refer to a relative location with respect to a reference element in the third direction D3. A level, a vertical level, height, or the like may be a distance from a lower surface of the substrate 100 in the third direction D3. For example, a higher level may mean a farther distance from the lower surface of the substrate 100 in the third direction D3, and a lower level may mean a closer distance to the lower surface of the substrate 100 in the third direction D3.

The first middle sheet pattern NS2_1 may be disposed on the first lower sheet pattern NS1_1. The first middle sheet pattern NS2_1 may be disposed to be spaced apart from the first lower sheet pattern NS1_1 in the third direction D3. The second middle sheet pattern NS2_2 may be disposed on the second lower sheet pattern NS1_2. The second middle sheet pattern NS2_2 may be disposed to be spaced apart from the second lower sheet pattern NS1_2 in the third direction D3. The second middle sheet pattern NS2_2 may be disposed to be spaced apart from the first middle sheet pattern NS2_1 in the first direction D1. The second middle sheet pattern NS2_2 may be disposed at the same vertical level as the first middle sheet pattern NS2_1. For example, the second middle sheet pattern NS2_2 may overlap the first middle sheet pattern NS2_1 in the first direction D1. The first middle sheet pattern NS2_1 may overlap the first lower sheet pattern NS1_1 in the third direction D3, and the second middle sheet pattern NS2_2 may overlap the second lower sheet pattern NS1_2 in the third direction D3.

The first upper sheet pattern NS3_1 may be disposed on the first middle sheet pattern NS2_1. The first upper sheet pattern NS3_1 may be disposed to be spaced apart from the first middle sheet pattern NS2_1 in the third direction D3. The second upper sheet pattern NS3_2 may be disposed on the second middle sheet pattern NS2_2. The second upper sheet pattern NS3_2 may be disposed to be spaced apart from the second middle sheet pattern NS2_2 in the third direction D3. The second upper sheet pattern NS3_2 may be disposed to be spaced apart from the first upper sheet pattern NS3_1 in the first direction D1. The second upper sheet pattern NS3_2 may be disposed at the same vertical level as the first upper sheet pattern NS3_1. For example, the second upper sheet pattern NS3_2 may overlap the first upper sheet pattern NS3_1 in the first direction D1. The first upper sheet pattern NS3_1 may overlap the first middle sheet pattern NS2_1 in the third direction D3, and the second upper sheet pattern NS3_2 may overlap the second middle sheet pattern NS2_2 in the third direction D3.

In some embodiments, a plurality of first and second lower sheet patterns NS1_1 and NS1_2, the first and second middle sheet patterns NS2_1 and NS2_2, and the first and second upper sheet patterns NS3_1 and NS3_2 may be provided, respectively. For example, the number of first lower sheet patterns NS1_1 may be three. A plurality of first lower sheet patterns NS1_1 may be disposed to be spaced apart from each other in the third direction D3.

The number of first lower sheet patterns NS1_1 may be the same as the number of second lower sheet patterns NS1_2. The number of the first middle sheet patterns NS2_1 may be the same as the number of the second middle sheet patterns NS2_2. The number of the first upper sheet patterns NS3_1 may be the same as the number of the second upper sheet patterns NS3_2.

It is illustrated that the number of first lower sheet patterns NS1_1, the number of first middle sheet patterns NS2_1, and the number of first upper sheet patterns NS3_1 is three, respectively, but embodiments are not limited thereto. For example, the number of first lower sheet patterns NS1_1, the number of first middle sheet patterns NS2_1, and the number of first upper sheet patterns NS3_1 may be partially the same or may all be different.

The first lower sheet pattern NS1_1 may be a channel region of the first pull-up transistor (e.g., the first pull-up transistor PU1 of FIG. 1). The second lower sheet pattern NS1_2 may be a channel region of the second pull-up transistor (e.g., the second pull-up transistor PU2 of FIG. 1). The first middle sheet pattern NS2_1 may be a channel region of the first pull-down transistor (e.g., the first pull-down transistor PD1 of FIG. 1). The second middle sheet pattern NS2_2 may be a channel region of the second pull-down transistor (e.g., the second pull-down transistor PD2 of FIG. 1). The first upper sheet pattern NS3_1 may be a channel region of the first pass transistor (e.g., the first pass transistor PG1 of FIG. 1). The second upper sheet pattern NS3_2 may be a channel region of the second pass transistor (e.g., the second pass transistor PG2 of FIG. 1).

Each of the first and second lower sheet patterns NS1_1 and NS1_2, the first and second middle sheet patterns NS2_1 and NS2_2, and the first and second upper sheet patterns NS3_1 and NS2_3 may include, for example, silicon (Si), silicon germanium (SiGe), a group IV-IV compound semiconductor, and/or a group III-V compound semiconductor.

For example, the group IV-IV compound semiconductor may be a binary compound or a ternary compound including at least two or more of carbon (C), silicon (Si), germanium (Ge), tin (Sn), or a compound doped with a group IV element.

For example, the group III-V compound semiconductor may be one of a binary compound, a ternary compound, or a quaternary compound formed by a combination of aluminum (Al), gallium (Ga), and/or indium (In) as a group III element and phosphorus (P), arsenic (As), and/or antimony (Sb) as a group V element.

The first lower gate electrode 120_1 may be disposed on the insulating pattern 101 and may extend in the second direction D2. The first lower gate electrode 120_1 may extend around (e.g., surround) the first lower sheet pattern NS1_1. For example, the first lower gate electrode 120_1 may extend around (e.g., surround) each of the plurality of first lower sheet patterns NS1_1.

The second lower gate electrode 120_2 may be disposed on the insulating pattern 101 and may extend in the second direction D2. The second lower gate electrode 120_2 may extend around (e.g., surround) the second lower sheet pattern NS1_2. For example, the second lower gate electrode 120_2 may extend around (e.g., surround) each of a plurality of second lower sheet patterns NS1_2. The second lower gate electrode 120_2 may be disposed to be spaced apart from the first lower gate electrode 120_1 in the first direction D1. The second lower gate electrode 120_2 may be disposed at the same vertical level as the first lower gate electrode 120_1. For example, the second lower gate electrode 120_2 may overlap the first lower gate electrode 120_1 in the first direction D1.

The first middle gate electrode 220_1 may be disposed on the first lower gate electrode 120_1. The first middle gate electrode 220_1 may extend in the second direction D2. The first middle gate electrode 220_1 may extend around (e.g., surround) the first middle sheet pattern NS2_1. For example, the first middle gate electrode 220_1 may extend around (e.g., surround) each of a plurality of first middle sheet patterns NS2_1.

The second middle gate electrode 220_2 may be disposed on the second lower gate electrode 120_2. The second middle gate electrode 220_2 may extend in the second direction D2. The second middle gate electrode 220_2 may extend around (e.g., surround) the second middle sheet pattern NS2_2. For example, the second middle gate electrode 220_2 may extend around (e.g., surround) each of a plurality of second middle sheet patterns NS2_2. The second middle gate electrode 220_2 may be disposed to be spaced apart from the first middle gate electrode 220_1 in the first direction D1. The second middle gate electrode 220_2 may be disposed at the same vertical level as the first middle gate electrode 220_1. For example, the second middle gate electrode 220_2 may overlap the first middle gate electrode 220_1 in the first direction D1.

The first lower gate electrode 120_1 and the first middle gate electrode 220_1 may be (electrically) connected to each other. The second lower gate electrode 120_2 and the second middle gate electrode 220_2 may be (electrically) connected to each other. That is, the first lower gate electrode 120_1 and the first middle gate electrode 220_1 may share the same signal, and the second lower gate electrode 120_2 and the second middle gate electrode 220_2 may share the same signal.

In some embodiments, the first lower gate electrode 120_1 may be in contact with the first middle gate electrode 220_1. The second lower gate electrode 120_2 may be in contact with the second middle gate electrode 220_2. At a vertical level overlapping a first interlayer insulating film ISP_1 in the third direction D3, the first lower gate electrode 120_1 may contact the first middle gate electrode 220_1, and the second lower gate electrode 120_2 may contact the second middle gate electrode 220_2. A boundary surface between the first lower gate electrode 120_1 and the first middle gate electrode 220_1 and a boundary surface between the second lower gate electrode 120_2 and the second middle gate electrode 220_2 may not be distinguished from each other.

The first upper gate electrode 320_1 may be disposed on the first middle gate electrode 220_1. The first upper gate electrode 320_1 may be disposed to be spaced apart from the first middle gate electrode 220_1 in the third direction D3. The first upper gate electrode 320_1 may extend in the second direction D2. The first upper gate electrode 320_1 may extend around (e.g., surround) the first upper sheet pattern NS3_1. For example, the first upper gate electrode 320_1 may extend around (e.g., surround) each of a plurality of first upper sheet patterns NS3_1.

The second upper gate electrode 320_2 may be disposed on the second middle gate electrode 220_2. The second upper gate electrode 320_2 may be disposed to be spaced apart from the second middle gate electrode 220_2 in the third direction D3. The second upper gate electrode 320_2 may extend in the second direction D2. The second upper gate electrode 320_2 may extend around (e.g., surround) the second upper sheet pattern NS3_2. For example, the second upper gate electrode 320_2 may extend around (e.g., surround) each of a plurality of second upper sheet patterns NS3_2. The second upper gate electrode 320_2 may be disposed to be spaced apart from the first upper gate electrode 320_1 in the first direction D1. The second upper gate electrode 320_2 may be disposed at the same vertical level as the first upper gate electrode 320_1. For example, the second upper gate electrode 320_2 may overlap the first upper gate electrode 320_1 in the first direction D1.

Each of the first and second lower gate electrodes 120_1 and 120_2, the first and second middle gate electrodes 220_1 and 220_2, and the first and second upper gate electrodes 320_1 and 320_2 may include, for example, a metal, a metal alloy, a conductive metal nitride, a metal silicide, a doped semiconductor material, a conductive metal oxide, and/or a conductive metal oxynitride. For example, each of the first and second lower gate electrodes 120_1 and 120_2 and the first and second middle gate electrodes 220_1 and 220_2, and the first and second upper gate electrodes 320_1 and 320_2 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof, but is not limited thereto.

Each of the first and second lower gate electrodes 120_1 and 120_2, the first and second middle gate electrodes 220_1 and 220_2, and the first and second upper gate electrodes 320_1 and 320_2 is illustrated as a single film, but embodiments are not limited thereto. For example, each of the first and second lower gate electrodes 120_1 and 120_2, the first and second middle gate electrodes 220_1 and 220_2, and the first and second upper gate electrodes 320_1 and 320_2 may include a work function adjusting film for adjusting a work function, and a filling conductive film for filling a space formed by the work function adjusting film. For example, the work function adjusting film may include TIN, TaN, TiC, TaC, TiAlC, and/or a combination thereof. For example, the filling conductive film may include W and/or Al.

In some embodiments, a portion of the first and second lower gate electrodes 120_1 and 120_2, of the first and second middle gate electrodes 220_1 and 220_2, and of the first and second upper gate electrodes 320_1 and 320_2 may include a work function adjustment film of different conductivity type. For example, the work function adjusting film of the first and second lower gate electrodes 120_1 and 120_2 may include a P-type work function adjusting film, and the work function adjusting film(s) of the first and second middle gate electrodes 220_1 and 220_2 and the first and second upper gate electrodes 320_1 and 320_2 may include an N-type work function adjusting film.

An upper stack isolation film 240 may be disposed between the first middle gate electrode 220_1 and the first upper gate electrode 320_1. In addition, the upper stack isolation film 240 may be disposed between the second middle gate electrode 220_2 and the second upper gate electrode 320_2. A width of the upper stack isolation film 240 disposed on the first middle gate electrode 220_1 in the first direction D1 may be the same as (equal to) a width of the first middle sheet pattern NS2_1 in the first direction D1. A width of the upper stack isolation film 240 disposed on the second middle gate electrode 220_2 in the first direction D1 may be the same as (equal to) a width of the second middle sheet pattern NS2_2 in the first direction D1. The upper stack isolation film 240 may include an insulating material.

A gate insulating film may be disposed on each of the first and second lower gate electrodes 120_1 and 120_2, the first and second middle gate electrodes 220_1 and 220_2, and the first and second upper gate electrodes 320_1 and 320_2. The gate insulating film may be disposed between the first lower gate electrode 120_1 and the first lower sheet pattern NS1_1. The gate insulating film may be disposed between the second lower gate electrode 120_2 and the second lower sheet pattern NS1_2. The gate insulating film may be disposed between the first middle gate electrode 220_1 and the first middle sheet pattern NS2_1. The gate insulating film may be disposed between the second middle gate electrode 220_2 and the second middle sheet pattern NS2_2. The gate insulating film may be disposed between the first upper gate electrode 320_1 and the first upper sheet pattern NS3_1. The gate insulating film may be disposed between the second upper gate electrode 320_2 and the second upper sheet pattern NS3_2.

In some embodiments, the gate insulating film may include a plurality of films. The gate insulating film may include a high-k insulating film and an interface insulating film. For example, the gate insulating film may include silicon oxide, silicon oxynitride, silicon nitride, and/or a high-k material having a dielectric constant greater than that of silicon oxide. For example, the high-k material may include boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

A gate capping pattern 340 may be disposed on an upper surface of the first upper gate electrode 320_1 and an upper surface of the second upper gate electrode 320_2. The gate capping pattern 340 may cover (overlap in the third direction D3) the upper surface of the first upper gate electrode 320_1 and the upper surface of the second upper gate electrode 320_2. An upper surface of the gate capping pattern 340 may be disposed in the same plane as (may be coplanar with) an upper surface of a third interlayer insulating film ISP_3.

In some embodiments, the gate capping pattern 340 may be disposed on an upper surface of a gate spacer 345. However, embodiments are not limited thereto. For example, the gate capping pattern 340 may be disposed between gate spacers 345. However, embodiments are not limited thereto.

For example, the gate capping pattern 340 may include silicon nitride (SiN), silicon oxynitride (SiON), silicon carbon nitride (SiCN), silicon oxycarbonitride (SiOCN), and/or a combination thereof. The gate capping pattern 340 may include a material having etch selectivity with respect to the third interlayer insulating film ISP_3.

The gate spacer 345 may be disposed on a side surface of the first upper gate electrode 320_1 and a side surface of the second upper gate electrode 320_2. The gate spacers 345 may be disposed on both side surfaces (e.g., side surfaces opposite to each other in the first direction D1) of the first upper gate electrode 320_1, of the first upper gate electrodes 320_1, which is disposed on an upper surface of the uppermost first upper sheet pattern NS3_1. The gate spacers 345 may be disposed on both side surfaces (e.g., side surfaces opposite to each other in the first direction D1) of the second upper gate electrode 320_2, of the second upper gate electrodes 320_2, which is disposed on an upper surface of the uppermost second upper sheet pattern NS3_2.

For example, the gate spacer 345 may include silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and/or a combination thereof. Although it is illustrated that the gate spacer 345 is a single film, it is only for convenience of description, and embodiments are not limited thereto.

The first, second, third, and fourth lower source/drain patterns 150_1, 150_2, 150_3, and 150_4 may be disposed on the insulating pattern 101. The first and second lower source/drain patterns 150_1 and 150_2 may be disposed on both sides (e.g., opposite sides) of the first lower sheet pattern NS1_1 in the first direction D1, respectively. The third and fourth lower source/drain patterns 150_3 and 150_4 may be disposed on both sides (e.g., opposite sides) of the second lower sheet pattern NS1_2 in the first direction D1, respectively. The second lower source/drain pattern 150_2 may be spaced apart from the third lower source/drain pattern 150_3 in the first direction D1. A dummy insulating film 110 may be disposed between the second lower source/drain pattern 150_2 and the third lower source/drain pattern 150_3 (in the first direction D1). The first, second, third, and fourth lower source/drain patterns 150_1, 150_2, 150_3, and 150_4 may all be disposed at the same vertical level. For example, the first, second, third, and fourth lower source/drain patterns 150_1, 150_2, 150_3, and 150_4 may overlap each other in the first direction D1.

The first interlayer insulating film ISP_1 may be disposed on upper surfaces of the first, second, third, and fourth lower source/drain patterns 150_1, 150_2, 150_3, and 150_4. The first interlayer insulating film ISP_1 may be disposed between the first lower source/drain pattern 150_1 and the first middle source/drain pattern 250_1 (in the third direction D3) and between the second lower source/drain pattern 150_2 and the second middle source/drain pattern 250_2 (in the third direction D3). In addition, the first interlayer insulating film ISP_1 may be disposed between the third lower source/drain pattern 150_3 and the third middle source/drain pattern 250_3 (in the third direction D3), and between the fourth lower source/drain pattern 150_4 and the fourth middle source/drain pattern 250_4 (in the third direction D3). Each of the first, second, third, and fourth lower source/drain patterns 150_1, 150_2, 150_3, and 150_4 may be spaced apart from each of the first, second, third, and fourth middle source/drain patterns 250_1, 250_2, 250_3, and 250_4 in the third direction D3, respectively, by the first interlayer insulating film ISP_1.

The first, second, third, and fourth middle source/drain patterns 250_1, 250_2, 250_3, and 250_4 may be disposed on the first interlayer insulating film ISP_1. The first and second middle source/drain patterns 250_1 and 250_2 may be disposed on both sides (e.g., opposite sides) of the first middle sheet pattern NS2_1 in the first direction D1, respectively. The third and fourth middle source/drain patterns 250_3 and 250_4 may be disposed on both sides (e.g., opposite sides) of the second middle sheet pattern NS2_2 in the first direction D1, respectively. The second middle source/drain pattern 250_2 may be spaced apart from the third middle source/drain pattern 250_3 in the first direction D1. The dummy insulating film 110 may be disposed between the second middle source/drain pattern 250_2 and the third middle source/drain pattern 250_3 (in the first direction D1). The first, second, third, and fourth middle source/drain patterns 250_1, 250_2, 250_3, and 250_4 may all be disposed at the same vertical level. For example, the first, second, third, and fourth middle source/drain patterns 250_1, 250_2, 250_3, and 250_4 may overlap each other in the first direction D1.

A second interlayer insulating film ISP_2 may be disposed on upper surfaces of the first, second, third, and fourth middle source/drain patterns 250_1, 250_2, 250_3, and 250_4. The second interlayer insulating film ISP_2 may be disposed between the first middle source/drain pattern 250_1 and the first upper source/drain pattern 350_1 (in the third direction D3) and between the second middle source/drain pattern 250_2 and the second upper source/drain pattern 350_2 (in the third direction D3). In addition, the second interlayer insulating film ISP_2 may be disposed between the third middle source/drain pattern 250_3 and the third upper source/drain pattern 350_3 (in the third direction D3) and between the fourth middle source/drain pattern 250_4 and the fourth upper source/drain pattern 350_4 (in the third direction D3). Each of the first, second, third, and fourth middle source/drain patterns 250_1, 250_2, 250_3, and 250_4 may be spaced apart from each of the first, second, third, and fourth upper source/drain patterns 350_1, 350_2, 350_3, and 350_4, respectively, in the third direction D3 by the second interlayer insulating film ISP_2.

The first, second, third, and fourth upper source/drain patterns 350_1, 350_2, 350_3, and 350_4 may be disposed on the second interlayer insulating film ISP_2. The first and second upper source/drain patterns 350_1 and 350_2 may be disposed on both sides (e.g., opposite sides) of the first upper sheet pattern NS3_1 in the first direction D1, respectively. The third and fourth upper source/drain patterns 350_3 and 350_4 may be disposed on both sides (e.g., opposite sides) of the second upper sheet pattern NS3_2 in the first direction D1, respectively. The second upper source/drain pattern 350_2 may be spaced apart from the third upper source/drain pattern 350_3 in the first direction D1. The dummy insulating film 110 may be disposed between the second upper source/drain pattern 350_2 and the third upper source/drain pattern 350_3 (in the first direction D1). The first, second, third, and fourth upper source/drain patterns 350_1, 350_2, 350_3, and 350_4 may all be disposed at the same vertical level. For example, the first, second, third, and fourth upper source/drain patterns 350_1, 350_2, 350_3, and 350_4 may overlap each other in the first direction D1.

The third interlayer insulating film ISP_3 may be disposed on upper surfaces of the first, second, third, and fourth upper source/drain patterns 350_1, 350_2, 350_3, and 350_4. The third interlayer insulating film ISP_3 may be disposed between each of the first, second, third, and fourth upper source/drain patterns 350_1, 350_2, 350_3, and 350_4 and an upper wiring insulating film 450 (in the third direction D3). In some embodiments, an upper surface of the third interlayer insulating film ISP_3, an upper surface of the gate capping pattern 340, and an upper surface of the dummy insulating film 110 may be disposed on the same plane (may be coplanar with each other). However, embodiments are not limited thereto.

In describing the materials of each of the first, second, third, and fourth lower source/drain patterns 150_1, 150_2, 150_3, and 150_4, the first, second, third, and fourth middle source/drain patterns 250_1, 250_2, 250_3, and 250_4, and the first, second, third, and fourth upper source/drain patterns 350_1, 350_2, 350_3, and 350_4, the description of the same materials may be replaced with the description of those of the first lower source/drain pattern 150_1.

The first lower source/drain pattern 150_1 may include an epitaxial pattern. The first lower source/drain pattern 150_1 may include a semiconductor material. For example, the first lower source/drain pattern 150_1 may include an element semiconductor material such as silicon (Si) or germanium (Ge). In addition, for example, the first lower source/drain pattern 150_1 may include a binary compound and/or a ternary compound including at least two or more of carbon (C), silicon (Si), germanium (Ge), tin (Sn), or a compound doped with a group IV element. For example, the first lower source/drain pattern 150_1 may include silicon (Si), silicon-germanium (SiGe), germanium (Ge), silicon carbide (SiC), etc., but embodiments are not limited thereto.

In some embodiments, the first, second, third, and fourth lower source/drain patterns 150_1, 150_2, 150_3, and 150_4 may have a first conductivity type, and the first, second, third, and fourth middle source/drain patterns 250_1, 250_2, 250_3, and 250_4 and the first, second, third, and fourth upper source/drain patterns 350_1, 350_2, 350_3, and 350_4 may have a second conductivity type. The second conductivity type may be different from the first conductivity type. In some embodiments, the first conductivity type may be a P-type and the second conductivity type may be an N-type. However, embodiments are not limited thereto.

For example, each of the first, second, and third interlayer insulating films ISP_1, ISP_2, and ISP_3 may include silicon oxide (SiO), silicon nitride (SiN), silicon oxynitride (SiON), and/or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or a combination thereof. However, embodiments are not limited to the above.

The dummy insulating film 110 may be disposed on the insulating pattern 101. The dummy insulating film 110 may extend in the second and third directions D2 and D3. The dummy insulating film 110 may be disposed between the second lower source/drain pattern 150_2 and the third lower source/drain pattern 150_3 (in the first direction D1), between the second middle source/drain pattern 250_2 and the third middle source/drain pattern 250_3 (in the first direction D1), and between the second upper source/drain pattern 350_2 and the third upper source/drain pattern 350_3 (in the first direction D1).

The dummy insulating film 110 may include an insulating material. For example, the dummy insulating film 110 may include silicon oxide, silicon nitride, silicon oxynitride, and/or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or a combination thereof. However, embodiments are not limited thereto.

The first lower source/drain contact 160_1 may be formed through (may extend in) the substrate 100 and the insulating pattern 101. The first lower source/drain contact 160_1 may be formed through a lower surface of the first lower source/drain pattern 150_1. The first lower source/drain contact 160_1 may extend into the first lower source/drain pattern 150_1. One end (e.g., an upper end) of the first lower source/drain contact 160_1 may be disposed in the first lower source/drain pattern 150_1. The first lower source/drain contact 160_1 may be (electrically) connected to the first lower source/drain pattern 150_1. The first lower silicide film 170_1 may be disposed between the first lower source/drain contact 160_1 and the first lower source/drain pattern 150_1.

The second lower source/drain contact 160_2 may be formed through (may extend in) the substrate 100 and the insulating pattern 101. The second lower source/drain contact 160_2 may be formed through a lower surface of the fourth lower source/drain pattern 150_4. The second lower source/drain contact 160_2 may extend into the fourth lower source/drain pattern 150_4. One end (e.g., an upper end) of the second lower source/drain contact 160_2 may be disposed in the fourth lower source/drain pattern 150_4. The second lower source/drain contact 160_2 may be (electrically) connected to the fourth lower source/drain pattern 150_4. The second lower silicide film 170_2 may be disposed between the second lower source/drain contact 160_2 and the fourth lower source/drain pattern 150_4.

The first lower source/drain contact 160_1 may be (electrically) connected to a first power line VDL_1. The second lower source/drain contact 160_2 may be (electrically) connected to a second power line VDL_2. Each of the first power line VDL_1 and the second power line VDL_2 may be disposed under (below) the substrate 100. For example, each of the first power line VDL_1 and the second power line VDL_2 may be disposed in a lower wiring insulating film 430 disposed on a lower surface of the substrate 100. The VDD voltage of FIG. 1 may be applied to each of the first power line VDL_1 and the second power line VDL_2.

The first middle source/drain contact 260_1 may be formed through (may extend in) the substrate 100, the insulating pattern 101, and the first lower source/drain pattern 150_1. The first middle source/drain contact 260_1 may extend in the third direction D3. The first middle source/drain contact 260_1 may be formed through a lower surface of the first middle source/drain pattern 250_1. The first middle source/drain contact 260_1 may extend into the first middle source/drain pattern 250_1. For example, one end (e.g., an upper end) of the first middle source/drain contact 260_1 may be disposed in the first middle source/drain pattern 250_1.

In some embodiments, the width of the first middle source/drain contact 260_1 in the first direction D1 may decrease as the distance from the substrate 100 (in the third direction D3) increases. However, embodiments are not limited thereto. For example, the width of the first middle source/drain contact 260_1 may be constant in the first direction D1.

The first middle source/drain contact 260_1 may be (electrically) connected to the first middle source/drain pattern 250_1. The first contact insulating film 265_1 may be disposed in the first lower source/drain pattern 150_1. The first contact insulating film 265_1 may extend around (e.g., surround) a portion of the first middle source/drain contact 260_1. For example, the first contact insulating film 265_1 may extend around (e.g., surround) a side surface of the first middle source/drain contact 260_1 disposed in the first lower source/drain pattern 150_1. Accordingly, the first middle source/drain contact 260_1 may be (electrically) insulated from the first lower source/drain pattern 150_1 (by the first contact insulating film 265_1). The first middle silicide film 270_1 may be disposed between the first middle source/drain contact 260_1 and the first middle source/drain pattern 250_1.

The second middle source/drain contact 260_2 may be formed through (may extend in) the substrate 100, the insulating pattern 101, and the fourth lower source/drain pattern 150_4. The second middle source/drain contact 260_2 may extend in the third direction D3. The second middle source/drain contact 260_2 may be formed through a lower surface of the fourth middle source/drain pattern 250_4. The second middle source/drain contact 260_2 may extend into the fourth middle source/drain pattern 250_4. For example, one end (e.g., an upper end) of the second middle source/drain contact 260_2 may be disposed in the fourth middle source/drain pattern 250_4.

In some embodiments, the width of the second middle source/drain contact 260_2 in the first direction D1 may decrease as the distance from the substrate 100 (in the third direction D3) increases. However, embodiments are not limited thereto. For example, the width of the second middle source/drain contact 260_2 may be constant in the first direction D1.

The second middle source/drain contact 260_2 may be (electrically) connected to the fourth middle source/drain pattern 250_4. The second contact insulating film 265_2 may be disposed in the fourth lower source/drain pattern 150_4. The second contact insulating film 265_2 may extend around (e.g., surround) a portion of the second middle source/drain contact 260_2. For example, the second contact insulating film 265_2 may extend around (e.g., surround) a side surface of the second middle source/drain contact 260_2 disposed in the fourth lower source/drain pattern 150_4. Accordingly, the second middle source/drain contact 260_2 may be (electrically) insulated from the fourth lower source/drain pattern 150_4 (by the second contact insulating film 265_2). The second middle silicide film 270_2 may be disposed between the second middle source/drain contact 260_2 and the fourth middle source/drain pattern 250_4.

The first middle source/drain contact 260_1 may be (electrically) connected to a third power line VSL_1. The second middle source/drain contact 260_2 may be (electrically) connected to a fourth power line VSL_2. Each of the third power line VSL_1 and the fourth power line VSL_2 may be disposed under (below) the substrate 100. For example, each of the third power line VSL_1 and the fourth power line VSL_2 may be disposed in the lower wiring insulating film 430 disposed on the lower surface of the substrate 100. The VSS voltage of FIG. 1 may be applied to each of the third power line VSL_1 and the fourth power line VSL_2.

The first middle source/drain contact 260_1 and the first lower source/drain contact 160_1 may be disposed to be spaced apart from each other in the second direction D2. In some embodiments, at least a portion of the first middle source/drain contact 260_1 may overlap the first lower source/drain contact 160_1 in the second direction D2. The first middle source/drain contact 260_1 and the first lower source/drain contact 160_1 may be disposed on a virtual straight line extending in the second direction D2. The first middle source/drain contact 260_1 and the first lower source/drain contact 160_1 may be aligned in the second direction D2 such that the integration density of the semiconductor device may be improved.

The second middle source/drain contact 260_2 and the second lower source/drain contact 160_2 may be disposed to be spaced apart from each other in the second direction D2. In some embodiments, at least a portion of the second middle source/drain contact 260_2 may overlap the second lower source/drain contact 160_2 in the second direction D2. The second middle source/drain contact 260_2 and the second lower source/drain contact 160_2 may be disposed on a virtual straight line extending in the second direction D2. The second middle source/drain contact 260_2 and the second lower source/drain contact 160_2 may be aligned in the second direction D2 such that the integration density of the semiconductor device may be improved.

Although it is illustrated that the first lower source/drain contact 160_1 and the second lower source/drain contact 160_2 overlap each other in the first direction D1, and that the first middle source/drain contact 260_1 and the second middle source/drain contact 260_2 overlap each other in the first direction D1, embodiments are not limited thereto. For example, the first lower source/drain contact 160_1 and the second middle source/drain contact 260_2 may overlap each other in the first direction D1, and the second lower source/drain contact 160_2 and the first middle source/drain contact 260_1 may overlap each other in the first direction D1.

The first merged through contact MTC_1 may be formed through (may extend in) the substrate 100 and the insulating pattern 101 and extend in the third direction D3. The first merged through contact MTC_1 may be formed through (may extend in) at least a portion of the second lower source/drain pattern 150_2, at least a portion of the second middle source/drain pattern 250_2, at least a portion of the second upper source/drain pattern 350_2, and at least a portion of the dummy insulating film 110. The first merged through contact MTC_1 may extend into the second upper source/drain pattern 350_2. One end (e.g., an upper end) of the first merged through contact MTC_1 may be disposed in the second upper source/drain pattern 350_2. The first merged through contact MTC_1 may be (electrically) connected to each of the second lower source/drain pattern 150_2, the second middle source/drain pattern 250_2, and the second upper source/drain pattern 350_2. The integration density of the semiconductor device may be improved by arranging the first merged through contact MTC_1.

In some embodiments, the width of the first merged through contact MTC_1 in the first direction D1 may decrease as the distance from the substrate 100 (in the third direction D3) increases. However, embodiments are not limited thereto. For example, the width of the first merged through contact MTC_1 may be constant in the first direction D1.

Although the first merged through contact MTC_1 is illustrated as formed through (overlapping in the third direction D3) a portion of the dummy insulating film 110, embodiments are not limited thereto. For example, the first merged through contact MTC_1 may not be formed through (may not overlap in the third direction D3) the dummy insulating film 110, but may be formed through (may extend in) the second lower source/drain pattern 150_2, the second middle source/drain pattern 250_2, and the second upper source/drain pattern 350_2, respectively.

The first through silicide film SC_1 may be disposed on the first merged through contact MTC_1. For example, the first through silicide film SC_1 may be disposed between the first merged through contact MTC_1 and the second lower source/drain pattern 150_2, between the first merged through contact MTC_1 and the second middle source/drain pattern 250_2, and between the first merged through contact MTC_1 and the second upper source/drain pattern 350_2.

The second merged through contact MTC_2 may be formed through (may extend in) the substrate 100 and the insulating pattern 101 and extend in the third direction D3. The second merged through contact MTC_2 may be formed through (may extend in) at least a portion of the third lower source/drain pattern 150_3, at least a portion of the third middle source/drain pattern 250_3, at least a portion of the third upper source/drain pattern 350_3, and at least a portion of the dummy insulating film 110. The second merged through contact MTC_2 may extend into the third upper source/drain pattern 350_3. One end (e.g., an upper end) of the second merged through contact MTC_2 may be disposed in the third upper source/drain pattern 350_3. The second merged through contact MTC_2 may be (electrically) connected to each of the third lower source/drain pattern 150_3, the third middle source/drain pattern 250_3, and the third upper source/drain pattern 350_3. The integration density of the semiconductor device may be improved by arranging the second merged through contact MTC_2.

In some embodiments, the width of the second merged through contact MTC_2 in the first direction D1 may decrease as the distance from the substrate 100 (in the third direction D3) increases. However, embodiments are not limited thereto. For example, the width of the second merged through contact MTC_2 may be constant in the first direction D1.

Although the second merged through contact MTC_2 is illustrated as formed through (overlapping in the third direction D3) a portion of the dummy insulating film 110, embodiments are not limited thereto. For example, the second merged through contact MTC_2 may not be formed through (may not overlap in the third direction D3) the dummy insulating film 110, but may be formed through (may extend in) the third lower source/drain pattern 150_3, the third middle source/drain pattern 250_3, and the third upper source/drain pattern 350_3, respectively.

The second through silicide film SC_2 may be disposed on the second merged through contact MTC_2. For example, the second through silicide film SC_2 may be disposed between the second merged through contact MTC_2 and the third lower source/drain pattern 150_3, between the second merged through contact MTC_2 and the third middle source/drain pattern 250_3, and between the second merged through contact MTC_2 and the third upper source/drain pattern 350_3, respectively.

The first merged through contact MTC_1 may be disposed to be spaced apart from the second merged through contact MTC_2 in the first direction D1 and the second direction D2.

When viewed in a plan view, each of the first merged through contact MTC_1 and the second merged through contact MTC_2 may be disposed between the first lower source/drain contact 160_1 and the second lower source/drain contact 160_2 (in the first direction D1). In addition, each of the first merged through contact MTC_1 and the second merged through contact MTC_2 may be disposed between the first middle source/drain contact 260_1 and the second middle source/drain contact 260_2 (in the first direction D1).

A first upper source/drain contact 360_1 may be disposed on the first upper source/drain pattern 350_1. The first upper source/drain contact 360_1 may be formed through (may extend in) upper surfaces of the third interlayer insulating film ISP_3 and the first upper source/drain pattern 350_1. The first upper source/drain contact 360_1 may extend in the third interlayer insulating film ISP_3 and extend into the first upper source/drain pattern 350_1 in the third direction D3. One end (e.g., a lower end) of the first upper source/drain contact 360_1 may be disposed in the first upper source/drain pattern 350_1. The first upper source/drain contact 360_1 may be (electrically) connected to the first upper source/drain pattern 350_1. A first upper silicide film 370_1 may be disposed between the first upper source/drain contact 360_1 and the first upper source/drain pattern 350_1.

A second upper source/drain contact 360_2 may be disposed on the fourth upper source/drain pattern 350_4. The second upper source/drain contact 360_2 may be formed through (may extend in) upper surfaces of the third interlayer insulating film ISP_3 and the fourth upper source/drain pattern 350_4. The second upper source/drain contact 360_2 may extend in the third interlayer insulating film ISP_3 and extend into the fourth upper source/drain pattern 350_4 in the third direction D3. One end (e.g., a lower end) of the second upper source/drain contact 360_2 may be disposed in the fourth upper source/drain pattern 350_4. The second upper source/drain contact 360_2 may be (electrically) connected to the fourth upper source/drain pattern 350_4. A second upper silicide film 370_2 may be disposed between the second upper source/drain contact 360_2 and the fourth upper source/drain pattern 350_4.

A first bit line BL_1 may be disposed on the first upper source/drain contact 360_1. The first upper source/drain contact 360_1 may be (electrically) connected to the first bit line BL_1. A second bit line BL_2 may be disposed on the second upper source/drain contact 360_2. The second upper source/drain contact 360_2 may be (electrically) connected to the second bit line BL_2. Each of the first bit line BL_1 and the second bit line BL_2 may extend in the second direction D2.

The first upper source/drain contact 360_1 may be aligned with (may overlap) each of the first lower source/drain contact 160_1 and the first middle source/drain contact 260_1 in the second direction D2. Although it is illustrated that the first upper source/drain contact 360_1 does not overlap each of the first lower source/drain contact 160_1 and the first middle source/drain contact 260_1 in the third direction D3, embodiments are not limited thereto. The first upper source/drain contact 360_1 may overlap (at least) a portion of the first lower source/drain contact 160_1 and/or (at least) a portion of the first middle source/drain contact 260_1 in the third direction D3.

The second upper source/drain contact 360_2 may be aligned with (may overlap) each of the second lower source/drain contact 160_2 and the second middle source/drain contact 260_2 in the second direction D2. Although it is illustrated that the second upper source/drain contact 360_2 does not overlap each of the second lower source/drain contact 160_2 and the second middle source/drain contact 260_2 in the third direction D3, embodiments are not limited thereto. The second upper source/drain contact 360_2 may overlap (at least) a portion of the second lower source/drain contact 160_2 and/or (at least) a portion of the second middle source/drain contact 260_2 in the third direction D3.

Each of the first and second lower source/drain contacts 160_1 and 160_2, the first and second middle source/drain contacts 260_1 and 260_2, and the first and second upper source/drain contacts 360_1 and 360_2 may include a contact barrier film and a filling conductive film. The filling conductive film may be disposed on the contact barrier layer.

For example, the contact barrier film may include tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (NbN), platinum (Pt), iridium (Ir), and/or rhodium (Rh). For example, the filling conductive film may include aluminum (Al), tungsten (W), cobalt (Co), ruthenium (Ru), and/or molybdenum (Mo).

Each of the first and second lower silicide films 170_1 and 170_2, the first and second middle silicide films 270_1 and 270_2, the first and second upper silicide films 370_1 and 370_2, and the first and second through contact silicide films SC_1 and SC_2 may include a metal silicide material.

The first lower gate contact 180_1 may be disposed on a lower surface of the first lower gate electrode 120_1. The first lower gate contact 180_1 may be formed through (may extend in) the substrate 100 and the insulating pattern 101 and (electrically) connected to the first lower gate electrode 120_1. The second lower gate contact 180_2 may be disposed on a lower surface of the second lower gate electrode 120_2. The second lower gate contact 180_2 may be formed through (may extend in) the substrate 100 and the insulating pattern 101 and (electrically) connected to the second lower gate electrode 120_2.

A first lower via 410_1 may be disposed on a lower surface of the first merged through contact MTC_1. A second lower via 410_2 may be disposed on a lower surface of the second lower gate contact 180_2. A first lower wiring 420_1 may be disposed on a lower surface of the first lower via 410_1 and a lower surface of the second lower via 410_2. The first lower wiring 420_1 may (electrically) connect the first lower via 410_1 to the second lower via 410_2. That is, the first merged through contact MTC_1 may be (electrically) connected to the second lower gate contact 180_2 through the first lower via 410_1, the first lower wiring 420_1, and the second lower via 410_2. At least a portion of the first lower wiring 420_1 may extend in the first direction D1.

A third lower via 410_3 may be disposed on a lower surface of the second merged through contact MTC_2. A fourth lower via 410_4 may be disposed on a lower surface of the first lower gate contact 180_1. A second lower wiring 420_2 may be disposed on a lower surface of the third lower via 410_3 and a lower surface of the fourth lower via 410_4. The second lower wiring 420_2 may (electrically) connect the third lower via 410_3 to the fourth lower via 410_4. That is, the second merged through contact MTC_2 may be (electrically) connected to the first lower gate contact 180_1 through the third lower via 410_3, the second lower wiring 420_2, and the fourth lower via 410_4. At least a portion of the second lower wiring 420_2 may extend in the first direction D1.

When viewed in a plan view, the first lower gate contact 180_1 may be disposed to be spaced apart from the second merged through contact MTC_2 in the first direction D1 and the second direction D2. The first lower gate contact 180_1 may not overlap the second merged through contact MTC_2 in the first direction D1. The second lower gate contact 180_2 may be disposed to be spaced apart from the first merged through contact MTC_1 in the first direction D1 and the second direction D2. The second lower gate electrode 180_2 may not overlap the first merged through contact MTC_1 in the first direction D1.

The first, second, third, and fourth lower vias 410_1, 410_2, 410_3, and 410_4 and the first and second lower wirings 420_1 and 420_2 may be disposed on a lower surface of the substrate 100. The first, second, third, and fourth lower vias 410_1, 410_2, 410_3, and 410_4 and the first and second lower wirings 420_1 and 420_2 may be disposed in the lower wiring insulating film 430. The lower wiring insulating film 430 may include a plurality of insulating layers. The first, second, third, and fourth lower vias 410_1, 410_2, 410_3, and 410_4 may be disposed at a vertical level different from the first and second lower wirings 420_1 and 420_2. For example, the lower wiring insulating film 430 may include silicon oxide, silicon nitride, silicon oxynitride, and/or a low-k material.

The first upper gate contact 380_1 may be disposed on the first upper gate electrode 320_1. The first upper gate contact 380_1 may extend through (may extend in) the gate capping pattern 340 and the upper surface of the first upper gate electrode 320_1. For example, the first upper gate contact 380_1 may extend into the first upper gate electrode 320_1 in the third direction D3. One end (e.g., a lower end) of the first upper gate contact 380_1 may be disposed in the first upper gate electrode 320_1. The first upper gate contact 380_1 may be (electrically) connected to the first upper gate electrode 320_1.

The second upper gate contact 380_2 may be disposed on the second upper gate electrode 320_2. The second upper gate contact 380_2 may be formed through (may extend in) the gate capping pattern 340 and the upper surface of the second upper gate electrode 320_2. For example, the second upper gate contact 380_2 may extend into the second upper gate electrode 320_2 in the third direction D3. One end (e.g., a lower end) of the second upper gate contact 380_2 may be disposed in the second upper gate electrode 320_2. The second upper gate contact 380_2 may be (electrically) connected to the second upper gate electrode 320_2.

A first upper via may be disposed on the upper surface of the first upper gate contact 380_1. A word line WL may be disposed on the first upper via. A second upper via may be disposed on the upper surface of the second upper gate contact 380_2. The word line WL may be disposed on the second upper via. The word line WL may extend in the first direction D1. The word line WL may be (electrically) connected to the first upper gate electrode 320_1 through the first upper via and the first upper gate contact 380_1 and may be (electrically) connected to the second upper gate electrode 320_2 through the second upper via and the second upper gate contact 380_2. The first upper gate electrode 320_1 and the second upper gate electrode 320_2 may share a signal.

The first upper via, the second upper via, and the word line WL may be disposed in the upper wiring insulating film 450. The upper wiring insulating film 450 may be disposed on the third interlayer insulating film ISP_3, the gate capping pattern 340, and the dummy insulating film 110. The upper wiring insulating film 450 may include a plurality of insulating films. For example, the upper wiring insulating film 450 may include silicon oxide, silicon nitride, silicon oxynitride, and/or a low-k material.

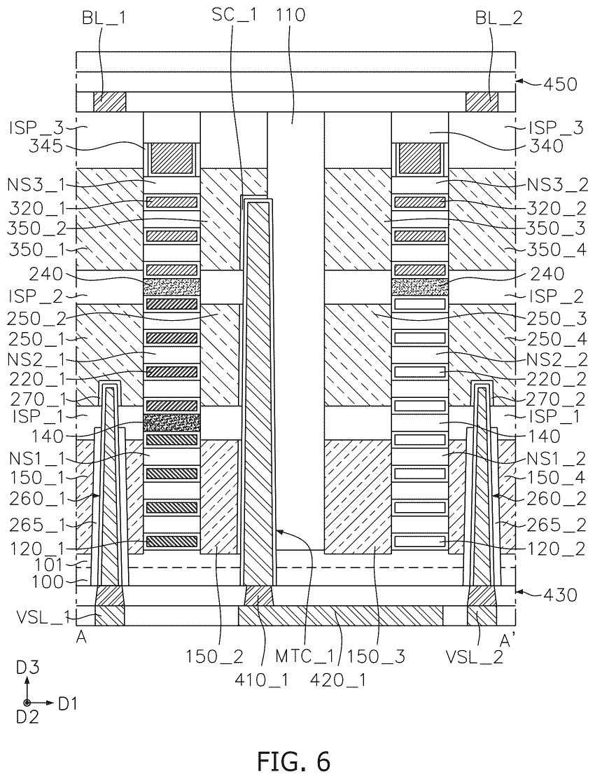

FIG. 6 is a diagram provided to explain a semiconductor device according to some embodiments. For reference, FIG. 6 may correspond to a cross-sectional view taken along line A-A′ of FIG. 2. For convenience of description, different configurations from those described in FIGS. 2 to 5 will be mainly described.

Referring to FIG. 6, in the semiconductor device according to some embodiments, the first lower gate electrode 120_1 and the first middle gate electrode 220_1 may be separated from each other, and the second lower gate electrode 120_2 and the second middle gate electrode 220_2 may be separated from each other.

In some embodiments, the semiconductor device may further include a lower stack isolation film 140 disposed between the first lower gate electrode 120_1 and the first middle gate electrode 220_1 (in the third direction D3). In addition, the lower stack isolation film 140 may be disposed between the second lower gate electrode 120_2 and the second middle gate electrode 220_2 (in the third direction D3).

A width of the lower stack isolation film 140 disposed on the first lower gate electrode 120_1 in the first direction D1 may be the same as (equal to) a width of the first lower sheet pattern NS1_1 in the first direction D1. A width of the lower stack isolation film 140 disposed on the second lower gate electrode 120_2 in the first direction D1 may be the same as (equal to) a width of the second lower sheet pattern NS1_2 in the first direction D1. The lower stack isolation film 140 may include an insulating material.

In some embodiments, the first lower gate electrode 120_1 and the first middle gate electrode 220_1 may not be in direct contact with each other, and the second lower gate electrode 120_2 and the second middle gate electrode 220_2 may not be in direct contact with each other. The first lower gate electrode 120_1 and the first middle gate electrode 220_1 may be (electrically) connected to each other through separate wires. In addition, the second lower gate electrode 120_2 and the second middle gate electrode 220_2 may be (electrically) connected to each other through separate wires. Accordingly, the first lower gate electrode 120_1 and the first middle gate electrode 220_1 may share a signal, and the second lower gate electrode 120_2 and the second middle gate electrode 220_2 may share a signal.

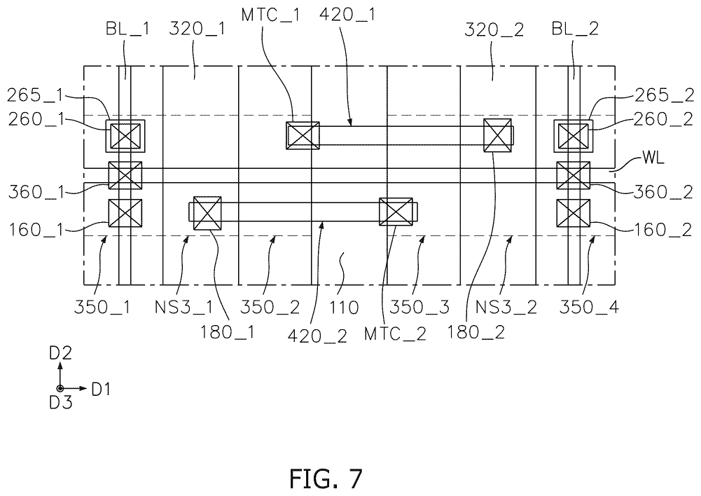

FIG. 7 is a diagram provided to explain a semiconductor device according to some embodiments. For convenience of description, different configurations from those described in FIGS. 2 to 5 will be mainly described.

Referring to FIG. 7, in a semiconductor device according to some embodiments, the first merged through contact MTC_1 may be aligned with the second lower gate contact 180_2 in the first direction D1. The first merged through contact MTC_1 may overlap the second lower gate contact 180_2 in the first direction D1. The first merged through contact MTC_1 may be disposed to be spaced apart from the second lower gate contact 180_2 in the first direction D1. The first lower wiring 420_1 may (electrically) connect the first merged through contact MTC_1 and the second lower gate contact 180_2. The first lower wiring 420_1 may have a linear shape extending in the first direction D1.

The second merged through contact MTC_2 may be aligned with the first lower gate contact 180_1 in the first direction D1. The second merged through contact MTC_2 may overlap the first lower gate contact 180_1 in the first direction D1. The second merged through contact MTC_2 may be disposed to be spaced apart from the first lower gate contact 180_1 in the first direction D1. The second lower wiring 420_2 may (electrically) connect the second merged through contact MTC_2 to the first lower gate contact 180_1. The second lower wiring 420_2 may have a linear shape extending in the first direction D1. The second lower wiring 420_2 may be spaced apart from the first lower wiring 420_1 in the second direction D2.

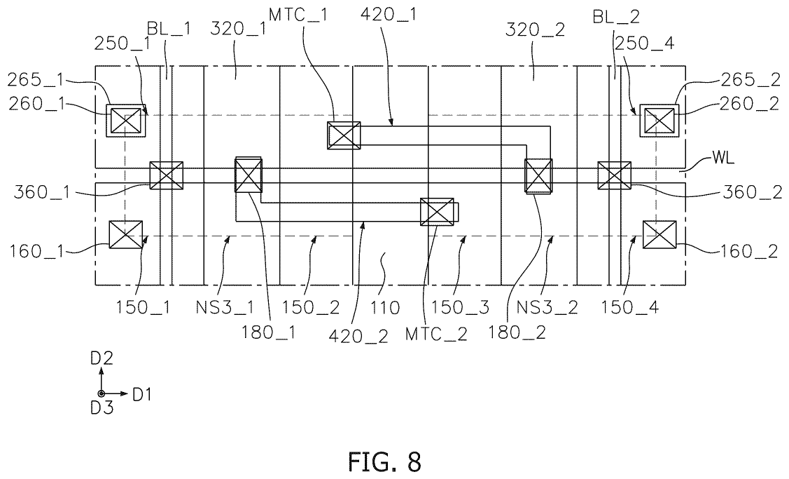

FIG. 8 is a diagram provided to explain a semiconductor device according to some embodiments. For convenience of description, different configurations from those described in FIGS. 2 to 5 will be mainly described.

Referring to FIG. 8, in the semiconductor device according to some embodiments, at least a portion of the first lower source/drain contact 160_1 may not overlap the first lower source/drain pattern 150_1 in the third direction D3. A portion of the first lower source/drain contact 160_1 may be disposed on the first lower source/drain pattern 150_1. At least a portion of the second lower source/drain contact 160_2 may not overlap the fourth lower source/drain pattern 150_4 in the third direction D3. A portion of the second lower source/drain contact 160_2 may be disposed on the fourth lower source/drain pattern 150_4.

At least a portion of the first middle source/drain contact 260_1 may not overlap the first middle source/drain pattern 250_1 in the third direction D3. A portion of the first middle source/drain contact 260_1 may be disposed on the first middle source/drain pattern 250_1. At least a portion of the second middle source/drain contact 260_2 may not overlap the fourth middle source/drain pattern 250_4 in the third direction D3. A portion of the second middle source/drain contact 260_2 may be disposed on the fourth middle source/drain pattern 250_4.

Unlike illustrated, at least a portion of the first upper source/drain contact 360_1 may not overlap the first middle source/drain pattern 250_1 in the third direction D3, and at least a portion of the second upper source/drain contact 360_2 may not overlap the fourth middle source/drain pattern 250_4 in the third direction D3.

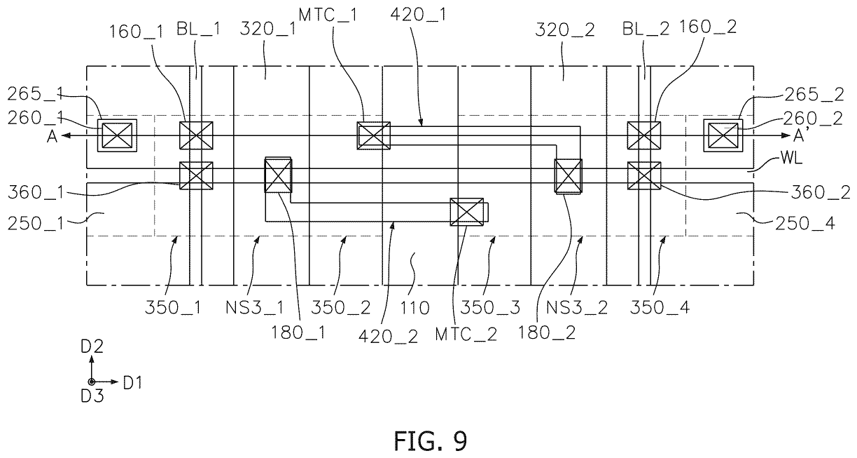

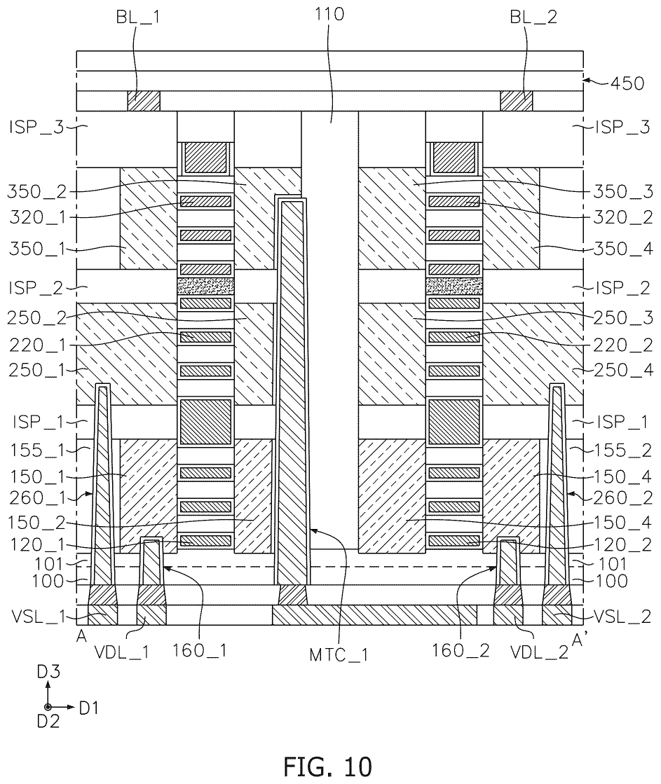

FIGS. 9 and 10 are diagrams provided to explain a semiconductor device according to some embodiments. For reference, FIG. 9 is a layout view of a semiconductor device according to some embodiments, and FIG. 10 is a cross-sectional view taken along line A-A′ of FIG. 9. For convenience of description, different configurations from those described in FIGS. 2 to 5 will be mainly described.

Referring to FIGS. 9 and 10, in the semiconductor device according to some embodiments, the first lower source/drain contact 160_1 and the first middle source/drain contact 260_1 may be aligned with each other in the first direction D1. The first lower source/drain contact 160_1 may be disposed to be spaced apart from the first middle source/drain contact 260_1 in the first direction D1. The first lower source/drain contact 160_1 may overlap the first middle source/drain contact 260_1 in the first direction D1.

The first middle source/drain contact 260_1 may be formed through (may extend in) the substrate 100, the insulating pattern 101, and a first lower insulating pattern 155_1. The first middle source/drain contact 260_1 may extend into the first middle source/drain pattern 250_1 in the third direction D3. One end (e.g., an upper end) of the first middle source/drain contact 260_1 may be in the first middle source/drain pattern 250_1. The first middle source/drain contact 260_1 may be (electrically) connected to the first middle source/drain pattern 250_1. The first lower insulating pattern 155_1 may be disposed on a side surface of the first lower source/drain pattern 150_1. The first lower insulating pattern 155_1 may be disposed at the same vertical level as the first lower source/drain pattern 150_1. For example, the first lower insulating pattern 155_1 may overlap the first lower source/drain pattern 150_1 in the first direction D1.

The width of the first middle source/drain pattern 250_1 in the first direction D1 may be greater than the width of the first lower source/drain pattern 150_1 in the first direction D1. In other words, the first middle source/drain pattern 250_1 may protrude further in the first direction D1 than the first lower source/drain pattern 150_1. The first middle source/drain contact 260_1 may be disposed on the protruding portion of the first middle source/drain pattern 250_1. For example, the first middle source/drain contact 260_1 may not overlap the first lower source/drain pattern 150_1 in the third direction D3.

The second lower source/drain contact 160_2 and the second middle source/drain contact 260_2 may be aligned with each other in the first direction D1. The second lower source/drain contact 160_2 may be disposed to be spaced apart from the second middle source/drain contact 260_2 in the first direction D1. The second lower source/drain contact 160_2 may overlap the second middle source/drain contact 260_2 in the first direction D1.

The second middle source/drain contact 260_2 may be formed through (may extend in) the substrate 100, the insulating pattern 101, and a second lower insulating pattern 155_2. The second middle source/drain contact 260_2 may extend into the fourth middle source/drain pattern 250_4 in the third direction D3. One end (e.g., an upper end) of the second middle source/drain contact 260_2 may be formed in the fourth middle source/drain pattern 250_4. The second middle source/drain contact 260_2 may be (electrically) connected to the fourth middle source/drain pattern 250_4. The second lower insulating pattern 155_2 may be disposed on the side surface of the fourth lower source/drain pattern 150_4. The second lower insulating pattern 155_2 may be disposed at the same vertical level as the fourth lower source/drain pattern 150_4. For example, the second lower insulating pattern 155_2 may overlap the fourth lower source/drain pattern 150_4 in the first direction D1.

The width of the fourth middle source/drain pattern 250_4 in the first direction D1 may be greater than the width of the fourth lower source/drain pattern 150_4 in the first direction D1. In other words, the fourth middle source/drain pattern 250_4 may protrude further in the first direction D1 than the fourth lower source/drain pattern 150_4. The second middle source/drain contact 260_2 may be disposed on the protruding portion of the fourth middle source/drain pattern 250_4. For example, the second middle source/drain contact 260_2 may not overlap the fourth lower source/drain pattern 150_4 in the third direction D3.

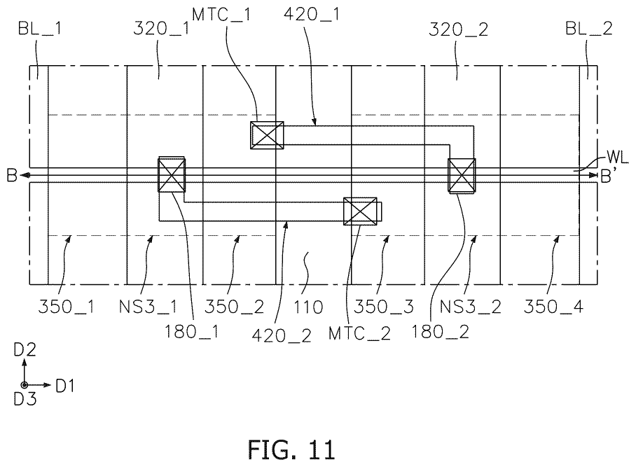

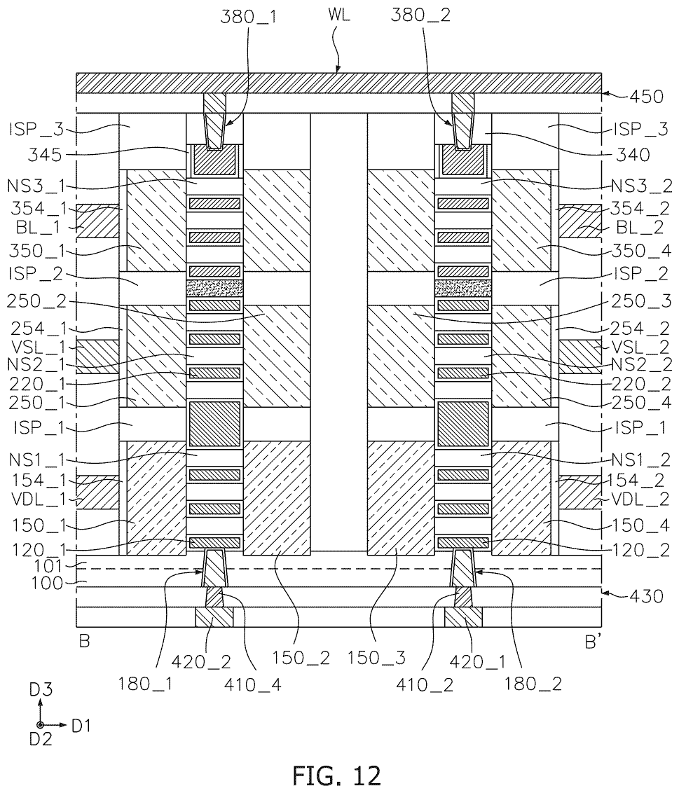

FIGS. 11 and 12 are diagrams provided to explain a semiconductor device according to some embodiments. For reference, FIG. 11 is a layout view of a semiconductor device according to some embodiments, and FIG. 12 is a cross-sectional view taken along line B-B′ of FIG. 11. For convenience of description, different configurations from those described in FIGS. 2 to 5 will be mainly described.

Referring to FIGS. 11 and 12, in a semiconductor device according to some embodiments, each of the first and second power lines VDL_1 and VDL_2, the third and fourth power lines VSL_1 and VSL_2, and the first and second bit lines BL_1 and BL_2 may extend in the second direction D2.

The first lower silicide film 154_1 and the first power line VDL_1 may be disposed on a side surface of the first lower source/drain pattern 150_1. The first lower silicide film 154_1 may extend along the side surface of the first lower source/drain pattern 150_1 in the second direction D2 and the third direction D3. The first power line VDL_1 may be disposed on a side surface of the first lower silicide film 154_1. The first power line VDL_1 may extend in the second direction D2. The first power line VDL_1 may be (electrically) connected to the first lower source/drain pattern 150_1.

The second lower silicide film 154_2 and a second power line VDL_2 may be disposed on a side surface of the fourth lower source/drain pattern 150_4. The second lower silicide film 154_2 may extend along the side surface of the fourth lower source/drain pattern 150_4 in the second direction D2 and the third direction D3. The second power line VDL_2 may be disposed on the side surface of the second lower silicide film 154_2. The second power line VDL_2 may extend in the second direction D2. The second power line VDL_2 may be (electrically) connected to the fourth lower source/drain pattern 150_4.

The first middle silicide film 254_1 and a third power line VSL_1 may be disposed on a side surface of the first middle source/drain pattern 250_1. The first middle silicide film 254_1 may extend along the side surface of the first middle source/drain pattern 250_1 in the second and third directions D2 and D3. The third power line VSL_1 may be disposed on the side surface of the first middle silicide film 254_1. The third power line VSL_1 may extend in the second direction D2. The third power line VSL_1 may be (electrically) connected to the first middle source/drain pattern 250_1.

The second middle silicide film 254_2 and a fourth power line VSL_2 may be disposed on a side surface of the fourth middle source/drain pattern 250_4. The second middle silicide film 254_2 may extend along the side surface of the fourth middle source/drain pattern 250_4 in the second and third directions D2 and D3. The fourth power line VSL_2 may be disposed on the side surface of the second middle silicide film 254_2. The fourth power line VSL_2 may extend in the second direction D2. The fourth power line VSL_2 may be (electrically) connected to the fourth middle source/drain pattern 250_4.

A first upper silicide film 354_1 and the first bit line BL_1 may be disposed on a side surface of the first upper source/drain pattern 350_1. The first upper silicide film 354_1 may extend along a side surface of the first upper source/drain pattern 350_1 in the second direction D2 and the third direction D3. The first bit line BL_1 may be disposed on a side surface of the first upper silicide film 354_1. The first bit line BL_1 may extend in the second direction D2. The first bit line BL_1 may be (electrically) connected to the first upper source/drain pattern 350_1.

A second upper silicide film 354_2 and the second bit line BL_2 may be disposed on a side surface of the fourth upper source/drain pattern 350_4. The second upper silicide film 354_2 may extend along the side surface of the fourth upper source/drain pattern 350_4 in the second direction D2 and the third direction D3. The second bit line BL_2 may be disposed on the side surface of the second upper silicide film 354_2. The second bit line BL_2 may extend in the second direction D2. The second bit line BL_2 may be (electrically) connected to the fourth upper source/drain pattern 350_4.

The first power line VDL_1, the third power line VSL_1, and the first bit line BL_1 may overlap each other in the third direction D3. The second power line VDL_2, the fourth power line VSL_2, and the second bit line BL_2 may overlap each other in the third direction D3.

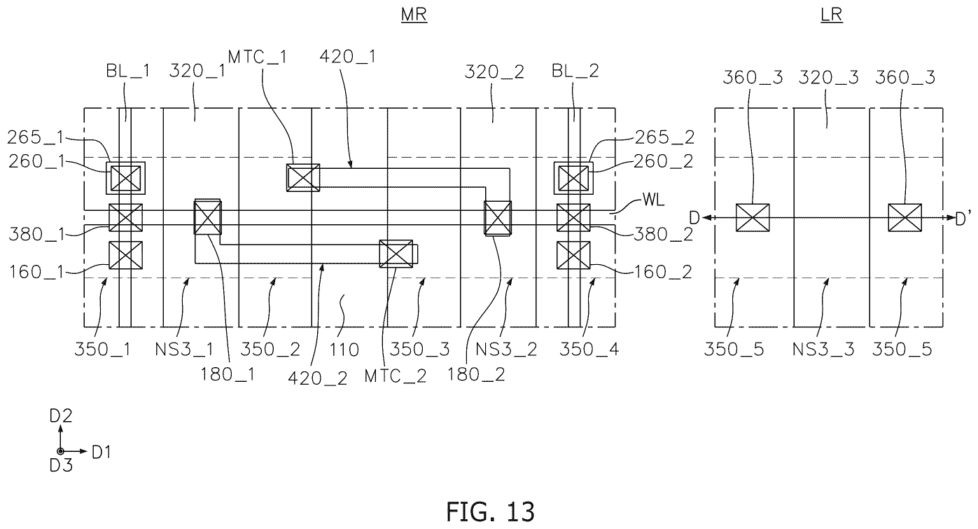

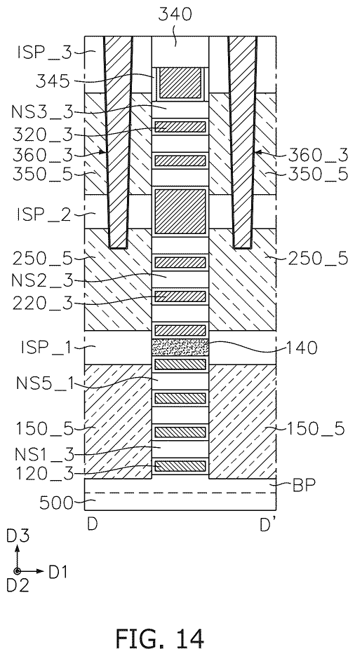

FIGS. 13 and 14 are diagrams provided to explain a semiconductor device according to some embodiments. For reference, FIG. 13 is a layout diagram provided to explain a semiconductor device according to some embodiments, and FIG. 14 is a cross-sectional view taken along line D-D′ of FIG. 13.

Referring to FIG. 13, a semiconductor device according to some embodiments may include a memory region MR and a logic region LR.

The memory region MR may be a region in which a plurality of memory cells are disposed. For example, a static random access memory (SRAM) cell may be disposed on (in) the memory region MR. Although it is illustrated that the SRAM cells described with reference to FIGS. 2 to 5 are disposed on (in) the memory region MR, embodiments are not limited thereto.

The logic region LR may be a region in which transistors forming a logic circuit are disposed. For example, a logic transistor may be disposed on (in) the logic region LR. The logic transistor may be a gate-all-around (GAA) transistor, but is not limited thereto.

The description of the SRAM cell disposed on (in) the memory region MR may be the same as that described with reference to FIGS. 2 to 5. Hereinafter, a logic transistor disposed on (in) the logic region LR will be described with reference to FIG. 14. Referring to FIG. 14, the logic transistor may include a substrate 500, a lower pattern BP, a third lower sheet pattern NS1_3, a third middle sheet pattern NS2_3, a third upper sheet pattern NS3_3, a third lower gate electrode 120_3, a third middle gate electrode 220_3, a third upper gate electrode 320_3, a fifth lower source/drain pattern 150_5, a fifth middle source/drain pattern 250_5, a fifth upper source/drain pattern 350_5, etc.

The substrate 500 may be a bulk silicon or a silicon-on-insulator (SOI). In some embodiments, the substrate 100 may include silicon germanium (SiGe), silicon germanium on insulator (SGOI), indium antimony, lead tellurium compound, indium arsenic, indium phosphide, gallium arsenic, and/or gallium antimony, but is not limited thereto.

In some embodiments, the substrate 500 may include the same insulating material as the substrate 100 of FIG. 3.

The lower pattern BP may be disposed on the upper surface of the substrate 100. The lower pattern BP may extend in the first direction D1. The lower pattern BP may protrude from the upper surface of the substrate 100 in the third direction D3. The lower pattern BP may include the same material as the substrate 500.

The third lower sheet pattern NS1_3 may be disposed on the lower pattern BP. The third middle sheet pattern NS2_3 may be disposed to be spaced apart from the third lower sheet pattern NS1_3 in the third direction D3. The third upper sheet pattern NS3_3 may be disposed to be spaced apart from the third middle sheet pattern NS2_3 in the third direction D3. The third upper sheet pattern NS3_3 may be on the third lower sheet pattern NS1_3, and the third middle sheet pattern may be between the third upper sheet pattern NS3_3 and the third lower sheet pattern NS1_3 in the third direction D3.

The fifth lower source/drain pattern 150_5 may be disposed on the substrate 500. The fifth lower source/drain pattern 150_5 may be disposed on both sides (e.g., opposite sides in the first direction D1) of the third lower sheet pattern NS1_3. The first interlayer insulating film ISP_1 may be disposed on an upper surface of the fifth lower source/drain pattern 150_5.

The fifth middle source/drain pattern 250_5 may be disposed on the first interlayer insulating film ISP_1. The fifth middle source/drain pattern 250_5 may be disposed on both sides (e.g., opposite sides in the first direction D1) of the third middle sheet pattern NS2_3. The second interlayer insulating film ISP_2 may be disposed on an upper surface of the fifth middle source/drain pattern 250_5.

The fifth upper source/drain pattern 350_5 may be disposed on the second interlayer insulating film ISP_2. The fifth upper source/drain pattern 350_5 may be disposed on both sides (e.g., opposite sides in the first direction D1) of the third upper sheet pattern NS3_3. The third interlayer insulating film ISP_3 may be disposed on an upper surface of the fifth upper source/drain pattern 350_5.

The third lower gate electrode 120_3 may be disposed on the lower pattern BP and may extend in the second direction D2. The third lower gate electrode 120_3 may extend around (e.g., surround) the third lower sheet pattern NS1_3.

The third middle gate electrode 220_3 may be disposed on the third lower gate electrode 120_3, and may extend in the second direction D2. The third middle gate electrode 220_3 may extend around (e.g., surround) the third middle sheet pattern NS2_3.

The third middle gate electrode 220_3 may be spaced apart from the third lower gate electrode 120_3 in the third direction D3. The lower stack isolation film 140 may be disposed between the third middle gate electrode 220_3 and the third lower gate electrode 120_3 (in the third direction D3). The third middle gate electrode 220_3 may not be (electrically) connected to the third lower gate electrode 120_3.

The third upper gate electrode 320_3 may be disposed on the third middle gate electrode 220_3, and may extend in the second direction D2. In some embodiments, the third upper gate electrode 320_3 may be in contact with the third middle gate electrode 220_3. For example, the third upper gate electrode 320_3 may be formed simultaneously with the third middle gate electrode 220_3. However, embodiments are not limited thereto.

In some embodiments, the third middle gate electrode 220_3 and the third upper gate electrode 320_3 may be integrally formed to be provided as a gate electrode of one transistor. For example, the third middle gate electrode 220_3 and the third upper gate electrode 320_3 may be provided as a gate electrode of an NMOS transistor. In this case, the NMOS transistor may be used as a high current transistor because the area of the channel in contact with the gate electrode increases.

A third upper source/drain contact 360_3 may be disposed on (in) the fifth upper source/drain pattern 350_5 and the fifth middle source/drain pattern 250_5. The third upper source/drain contact 360_3 may be formed through upper surfaces of the fifth upper source/drain pattern 350_5 and the fifth middle source/drain pattern 250_5. The third upper source/drain contact 360_3 may extend in the fifth upper source/drain pattern 350_5 and extend into the fifth middle source/drain pattern 250_5. The third upper source/drain contact 360_3 may be (electrically) connected to the fifth upper source/drain pattern 350_5 and the fifth middle source/drain pattern 250_5. Although not shown, a third lower source/drain contact may be disposed on (in) the fifth lower source/drain pattern 150_5.

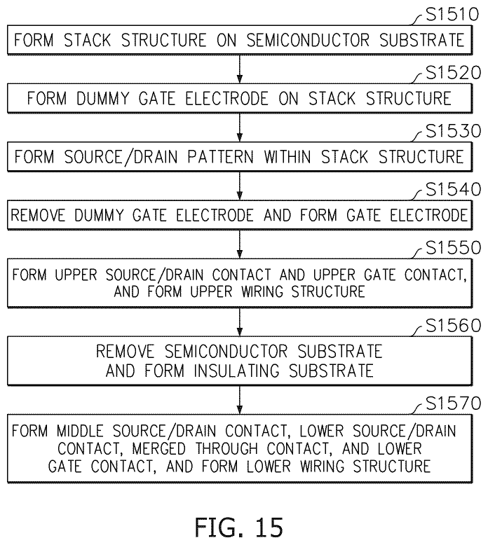

FIG. 15 is a flowchart provided to explain a method for manufacturing a semiconductor device according to some embodiments.

Referring to FIG. 15, the method of manufacturing the semiconductor device according to some embodiments may include forming a stack structure on a semiconductor substrate, at S1510. The stack structure may include a plurality of semiconductor layers and a plurality of sacrificial layers, which are alternately stacked. The stack structure may extend in the first direction (e.g., in the first direction D1).

A dummy gate electrode may be formed on the stack structure, at S1520. Specifically, a gate trench may be formed on the stack structure using a mask pattern, and a dummy gate electrode may be formed in the gate trench. The dummy gate electrode may extend in a second direction (e.g., in the second direction D2) intersecting the first direction.

A source/drain pattern may be formed in the stack structure, at S1530. Specifically, a source/drain trench may be formed on the stack structure. The source/drain trench may be spaced apart from the dummy gate electrode in the first direction. A source/drain pattern may be formed on the source/drain trench. The source/drain pattern may be epitaxially grown from the semiconductor layer. The source/drain pattern may include a lower source/drain pattern, a middle source/drain pattern, and an upper source/drain pattern.

The dummy gate electrode may be removed, and a gate electrode may be formed in the gate trench, at S1540. The gate electrode may include a lower gate electrode, a middle gate electrode, and an upper gate electrode. For example, the process of forming the gate electrode may be a replacement metal gate (RMG) process.

An upper source/drain contact may be formed on the upper source/drain pattern, a gate contact may be formed on the upper gate electrode, and an upper wiring structure may be formed, at S1550. The upper source/drain contact and the upper gate contact may be sequentially or simultaneously formed. The upper wiring structure may include a bit line (electrically) connected to the upper source/drain contact and a word line (electrically) connected to the upper gate contact.

The semiconductor substrate may be removed to form an insulating substrate, at S1560. For example, the semiconductor substrate is rotated 180 degrees, and the semiconductor substrate may be removed. An insulating substrate may be formed in a portion from which the semiconductor substrate has been removed.

A middle source/drain contact, a lower source/drain contact, a merged through contact, and a lower gate contact formed through the insulating substrate may be formed, and a lower wiring structure may be formed, at S1570. The lower source/drain contact may be formed through the insulating substrate to be (electrically) connected to the lower source/drain pattern. The middle source/drain contact may be formed through the lower source/drain pattern to be (electrically) connected to the middle source/drain pattern. The merged through contact may extend in the third direction (e.g., the third direction D3) perpendicular to the upper surface of the insulating substrate and (electrically) connected to the lower source/drain pattern, the middle source/drain pattern, and the upper source/drain pattern.

The lower wiring structure may be formed on the insulating substrate. The lower wiring structure may include a first power line, a second power line, and a lower wiring. The first power line may be (electrically) connected to the middle source/drain contact. The second power line may be (electrically) connected to the lower source/drain contact. The lower wiring may (electrically) connect the merged through contact to the lower gate contact.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor device, comprising:
a substrate;
a first lower sheet pattern on the substrate;
a second lower sheet pattern on the substrate, wherein the second lower sheet pattern is spaced apart from the first lower sheet pattern in a first direction that is parallel with an upper surface of the substrate;
a first lower gate electrode that extends around the first lower sheet pattern and extends in a second direction that is parallel with the upper surface of the substrate and intersects the first direction;
a second lower gate electrode that extends around the second lower sheet pattern and extends in the second direction;
a middle sheet pattern on the first lower sheet pattern, wherein the middle sheet pattern is spaced apart from the first lower sheet pattern in a third direction that is perpendicular to the upper surface of the substrate;
an upper sheet pattern on the middle sheet pattern, wherein the upper sheet pattern is spaced apart from the middle sheet pattern in the third direction;
a first lower source/drain pattern and a second lower source/drain pattern on opposite sides of the first lower sheet pattern in the first direction;
a first middle source/drain pattern and a second middle source/drain pattern on opposite sides of the middle sheet pattern in the first direction;
a first upper source/drain pattern and a second upper source/drain pattern on opposite sides of the upper sheet pattern in the first direction;
a merged through contact that extends in the second lower source/drain pattern, the second middle source/drain pattern, and the second upper source/drain pattern; and
a lower gate contact that extends in the substrate and is electrically connected to the second lower gate electrode,
wherein the merged through contact is spaced apart from the lower gate contact in the first direction.

2. The semiconductor device according to claim 1, further comprising:
a lower source/drain contact that extends in the substrate and is electrically connected to the first lower source/drain pattern; and
a middle source/drain contact that extends in the first lower source/drain pattern and is electrically connected to the first middle source/drain pattern,
wherein the middle source/drain contact is spaced apart from the lower source/drain contact in the second direction.

3. The semiconductor device according to claim 2, further comprising:
a contact insulating film that extends in the first lower source/drain pattern and extends around the middle source/drain contact.

4. The semiconductor device according to claim 1, further comprising:
a lower wiring on a lower surface of the substrate,
wherein the lower wiring electrically connects the lower gate contact and the merged through contact, and
wherein at least a portion of the lower wiring extends in the first direction.

5. The semiconductor device according to claim 1, further comprising:
an upper source/drain contact on the first upper source/drain pattern; and
a bit line that is electrically connected to the upper source/drain contact and extends in the second direction.

6. The semiconductor device according to claim 1, further comprising:
a lower source/drain contact that extends in the substrate and is electrically connected to the first lower source/drain pattern; and
a middle source/drain contact that extends in the first lower source/drain pattern and is electrically connected to the first middle source/drain pattern,
wherein the middle source/drain contact is spaced apart from the lower source/drain contact in the first direction.

7. The semiconductor device according to claim 6, wherein a width of the first middle source/drain pattern in the first direction is greater than a width of the first lower source/drain pattern in the first direction.

8. The semiconductor device according to claim 1, further comprising:
a first power line on a side surface of the first lower source/drain pattern, wherein the first power line extends in the second direction;
a second power line on a side surface of the first middle source/drain pattern, wherein the second power line extends in the second direction; and
a bit line on a side surface of the first upper source/drain pattern, wherein the bit line extends in the second direction.

9. The semiconductor device according to claim 8, wherein the first power line, the second power line, and the bit line overlap each other in the third direction.

10. The semiconductor device according to claim 1, further comprising:
an upper gate electrode that extends around the upper sheet pattern and extends in the second direction; and
a word line on the upper gate electrode, wherein the word line is electrically connected to the upper gate electrode and extends in the first direction.

11. A semiconductor device, comprising:
a substrate;
a first lower sheet pattern on the substrate;
a second lower sheet pattern on the substrate, wherein the second lower sheet pattern is spaced apart from the first lower sheet pattern in a first direction that is parallel with an upper surface of the substrate;
a first lower gate electrode that extends around the first lower sheet pattern and extends in a second direction that is parallel with the upper surface of the substrate and intersects the first direction;
a second lower gate electrode that extends around the second lower sheet pattern and extends in the second direction;
a first middle sheet pattern on the first lower sheet pattern, wherein the first middle sheet pattern is spaced apart from the first lower sheet pattern in a third direction that is perpendicular to the upper surface of the substrate;
a second middle sheet pattern on the second lower sheet pattern, wherein the second middle sheet pattern is spaced apart from the second lower sheet pattern in the third direction;
a first upper sheet pattern on the first middle sheet pattern, wherein the first upper sheet pattern is spaced apart from the first middle sheet pattern in the third direction;
a second upper sheet pattern on the second middle sheet pattern, wherein the second upper sheet pattern is spaced apart from the second middle sheet pattern in the third direction;
a first lower source/drain pattern and a second lower source/drain pattern on opposite sides of the first lower sheet pattern in the first direction;
a first middle source/drain pattern and a second middle source/drain pattern on opposite sides of the first middle sheet pattern in the first direction;
a middle source/drain contact that extends in the substrate and the first lower source/drain pattern and is electrically connected to the first middle source/drain pattern; and
a lower source/drain contact that is spaced apart from the middle source/drain contact in the second direction and is electrically connected to the first lower source/drain pattern,
wherein the middle source/drain contact overlaps the lower source/drain contact in the second direction.

12. The semiconductor device according to claim 11, further comprising:
a merged through contact that extends in the second lower source/drain pattern and the second middle source/drain pattern in the third direction,
wherein the second lower source/drain pattern and the second middle source/drain pattern are electrically connected to each other by the merged through contact.

13. The semiconductor device according to claim 12, further comprising:
a first upper source/drain pattern and a second upper source/drain pattern on opposite sides of the first upper sheet pattern in the first direction,
wherein the merged through contact is electrically connected to the second upper source/drain pattern.

14. The semiconductor device according to claim 12, further comprising:
a lower gate contact that extends in the substrate and is electrically connected to the second lower gate electrode,
wherein the lower gate contact is electrically connected to the merged through contact.

15. The semiconductor device according to claim 14, wherein the lower gate contact is spaced apart from the merged through contact in the first direction, and
wherein the merged through contact is between the lower gate contact and the lower source/drain contact in the first direction.

16. The semiconductor device according to claim 14, further comprising:
a lower wiring on a lower surface of the substrate, wherein the lower wiring electrically connects the lower gate contact and the merged through contact, and
wherein at least a portion of the lower wiring extends in the first direction.

17. The semiconductor device according to claim 12, further comprising:
a dummy insulating film on a side surface of the second lower source/drain pattern and a side surface of the second middle source/drain pattern, wherein the dummy insulating film extends in the second direction and the third direction, and
wherein a side surface of the merged through contact is in contact with the dummy insulating film.

18. The semiconductor device according to claim 11, further comprising:
a first middle gate electrode that extends around the first middle sheet pattern; and
a second middle gate electrode that extends around the second middle sheet pattern,
wherein the first middle gate electrode is in contact with the first lower gate electrode, and
wherein the second middle gate electrode is in contact with the second lower gate electrode.

19. The semiconductor device according to claim 11, further comprising:
a first upper source/drain pattern and a second upper source/drain pattern on opposite sides of the first upper sheet pattern in the first direction,
wherein the first lower source/drain pattern has a first conductivity type,
wherein the first middle source/drain pattern has a second conductivity type, and
wherein the first upper source/drain pattern has the second conductivity type.

20. A semiconductor device, comprising:
a substrate;
a first lower sheet pattern on the substrate;
a second lower sheet pattern on the substrate, wherein the second lower sheet pattern is spaced apart from the first lower sheet pattern in a first direction that is parallel with an upper surface of the substrate;
a first lower gate electrode that extends around the first lower sheet pattern and extends in a second direction that is parallel with the upper surface of the substrate and intersects the first direction;
a second lower gate electrode that extends around the second lower sheet pattern and extends in the second direction;
a first middle sheet pattern on the first lower sheet pattern, wherein the first middle sheet pattern is spaced apart from the first lower sheet pattern in a third direction that is perpendicular to the upper surface of the substrate;
a second middle sheet pattern on the second lower sheet pattern, wherein the second middle sheet pattern is spaced apart from the second lower sheet pattern in the third direction;
a first upper sheet pattern on the first middle sheet pattern, wherein the first upper sheet pattern is spaced apart from the first middle sheet pattern in the third direction;
a second upper sheet pattern on the second middle sheet pattern, wherein the second upper sheet pattern is spaced apart from the second middle sheet pattern in the third direction;
a first lower source/drain pattern and a second lower source/drain pattern on opposite sides of the first lower sheet pattern in the first direction;
a first middle source/drain pattern and a second middle source/drain pattern on opposite sides of the first middle sheet pattern in the first direction;
a first upper source/drain pattern and a second upper source/drain pattern on opposite sides of the first upper sheet pattern in the first direction;
a middle source/drain contact that extends in the substrate and the first lower source/drain pattern and is electrically connected to the first middle source/drain pattern;
a lower source/drain contact that extends in the substrate and is electrically connected to the first lower source/drain pattern, wherein the lower source/drain contact is spaced apart from the middle source/drain contact in the second direction;
a merged through contact that extends in the second lower source/drain pattern, the second middle source/drain pattern, and the second upper source/drain pattern in the third direction;
a lower gate contact that extends in the substrate and is electrically connected to the second lower gate electrode; and
a lower wiring on a lower surface of the substrate, wherein the lower wiring electrically connects the lower gate contact and the merged through contact,
wherein the middle source/drain contact overlaps the lower source/drain contact in the second direction.
